(19) United States
(12) Patent Application Publication
(10) Pub. No.: US 2026/0182147 A1
(43) Pub. Date: Jun. 25, 2026

(54) Display Substrate, Preparation Method Therefor, and Display Apparatus

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Changchang LIU, Beijing (CN); Hongting LU, Beijing (CN); Xiangfei HE, Beijing (CN); Hongbo MA, Beijing (CN)

(21) Appl. No.: 18/842,059

(22) PCT Filed: Sep. 13, 2023
(86) PCT No.: PCT/CN2023/118618

§ 371 Date: Aug. 28, 2024

(51) Int. Cl. H10K 59/121; H10K 59/12; H10K 59/131

(52) U.S. Cl. CPC H10K 59/1213; H10K 59/1201; H10K 59/131

(57) ABSTRACT

A display substrate includes a base substrate (101) and a circuit structure layer (102) disposed on the base substrate (101). The circuit structure layer (102) includes at least a plurality of circuit units, at least one circuit unit includes a pixel drive circuit, and the pixel drive circuit includes a plurality of drive transistors (T3). First electrodes of the plurality of drive transistors (T3) are connected to each other, second electrodes of the plurality of drive transistors (T3) are connected to each other, and gate electrodes of the plurality of drive transistors (T3) are connected to each other.

### CROSS-REFERENCE TO RELATED APPLICATIONS

The present application is a U.S. National Phase Entry of International Application PCT/CN2023/118618 having an international filing date of Sep. 13, 2023, and entire content of which is hereby incorporated by reference.

### TECHNICAL FIELD

The present disclosure relates to, but is not limited to, the field of display technologies, and particularly to a display substrate and a preparation method therefor, and a display apparatus.

### BACKGROUND

An Organic Light Emitting Diode (OLED) and a Quantum dot Light Emitting Diode (QLED) are active light emitting display devices and have advantages of self-illumination, a wide viewing angle, a high contrast ratio, low power consumption, an extremely high reaction speed, lightness and thinness, bendability, and a low cost, etc.

### SUMMARY

The following is a summary of subject matters described herein in detail. This summary is not intended to limit the protection scope of claims.

In one aspect, the present disclosure provides a display substrate including a base substrate and a circuit structure layer disposed on the base substrate, the circuit structure layer includes at least a plurality of circuit units, at least one of the circuit units includes a pixel drive circuit, the pixel drive circuit includes a plurality of drive transistors; first electrodes of the plurality of drive transistors are connected to each other, second electrodes of the plurality of drive transistors are connected to each other, and gate electrodes of the plurality of drive transistors are connected to each other.

In an exemplary implementation, the pixel drive circuit further includes a storage capacitor, the storage capacitor includes a first plate and a second plate, the second plate is located on a side of the first plate away from the base substrate, an orthographic projection of the first plate on the base substrate is at least partially overlapped with an orthographic projection of the second plate on the base substrate; the first plate includes a plurality of first sub-plates, and a single first sub-plate serves as a gate electrode of at least one of the drive transistors.

In an exemplary implementation, the plurality of first sub-plates of the first plate are independently disposed and electrically connected by a second connection electrode; the second connection electrode is located on a side of the second plate away from the base substrate.

In an exemplary implementation, the pixel drive circuit further includes a first initialization transistor and a threshold compensation transistor; a first electrode of the first initialization transistor is connected to a first initial signal line, and a second electrode of the first initialization transistor is connected to the gate electrodes of the plurality of drive transistors; a second electrode of the threshold compensation transistor is connected to the gate electrodes of the plurality of drive transistors, and a first electrode of the threshold compensation transistor is connected to the second electrodes of the plurality of drive transistors; the first initial transistor and the threshold compensation transistor are connected to the gate electrodes of the plurality of drive transistors through the second connection electrode.

In an exemplary implementation, in a direction perpendicular to the display substrate, the circuit structure layer includes at least a semiconductor layer, a first conductive layer, a second conductive layer, and a third conductive layer disposed sequentially on the base substrate; the first plate of the storage capacitor is located on the first conductive layer, the second plate is located on the second conductive layer, and the second connection electrode is located on the third conductive layer.

In an exemplary implementation, the plurality of drive transistors are sequentially arranged along a second direction, and the second plate of the storage capacitor extends along the second direction, and the second plate has a first end portion and a second end portion in the second direction; the first end portion and the second end portion of the second plate are respectively connected with a first power supply line; the first power supply line is located at a side of the second plate away from the base substrate.

In an exemplary implementation, the circuit structure layer further includes a data line connected to the pixel drive circuit and extending along the second direction, a first data transfer line extending along a first direction, and a second data transfer line extending along the second direction; the first direction intersects the second direction; the data line is connected to the second data transfer line through the first data transfer line; the first data transfer line is located at a side of the data line close to the base substrate, and the second data transfer line and the data line are disposed in a same layer.

In an exemplary implementation, the circuit structure layer further includes a first power supply line connected to the pixel drive circuit; the data line and the first power supply line are disposed in a same layer and arranged at intervals in the first direction.

In an exemplary implementation, the pixel drive circuit further includes a first initialization transistor, a first electrode of the first initialization transistor is connected to a first initial signal line and a second electrode of the first initialization transistor is connected to the gate electrodes of the plurality of drive transistors; the first initial signal line extends along a first direction, the first initial signal line is connected to a first initial signal connection line extending along a second direction, and the first direction intersects the second direction; the first initial signal connection line is located at a side of the first initial signal line away from the base substrate.

In an exemplary implementation, the pixel drive circuit further includes a second initialization transistor, a first electrode of the second initialization transistor is connected to a second initial signal line and a second electrode of the second initialization transistor is connected to a first electrode of a light emitting device to which the pixel drive circuit is connected; the second initial signal line extends along the first direction, and the second initial signal line is connected to a second initial signal connection line extending along the second direction; the second initial signal line and the first initial signal line are disposed in a same layer, and the second initial signal connection line and the first initial signal connection line are disposed in a same layer.

In an exemplary implementation, the pixel drive circuit further includes a first initialization transistor and a threshold compensation transistor; a first electrode of the first initialization transistor is connected to a first initial signal line, and a second electrode of the first initialization transistor is connected to the gate electrodes of the plurality of drive transistors; a second electrode of the threshold compensation transistor is connected to the gate electrodes of the plurality of drive transistors, and a first electrode of the threshold compensation transistor is connected to the second electrodes of the plurality of drive transistors; the first initial signal line is connected to a shielding electrode, an orthographic projection of the shielding electrode on the base substrate is at least partially overlapped with an orthographic projection of a conductivized region between channel regions of an active layer of the threshold compensation transistor on the base substrate; the shielding electrode and the first initial signal line are disposed in a same layer, and are located at a side of a gate electrode of the threshold compensation transistor away from the base substrate.

In an exemplary implementation, the first initial signal line is connected to the shielding electrode and the first initialization transistor through a first connection electrode; the first connection electrode is located at a side of the first initial signal line away from the base substrate.

In an exemplary implementation, the plurality of circuit units are divided into a plurality of circuit unit groups, each circuit unit group includes three pixel drive circuits arranged sequentially along a first direction, each pixel drive circuit in the circuit unit group is electrically connected to a first power supply line extending along a second direction; the circuit structure layer further includes at least one first connection ring, the first connection ring is electrically connected to three first power supply lines connected to three pixel drive circuits in the circuit unit group, and an orthographic projection of the first connection ring on the base substrate surrounds a periphery of the three pixel drive circuits; the first connection ring is located at a side of the first power supply line away from the base substrate.

In an exemplary implementation, the circuit structure layer further includes at least one first transmission ring, the first transmission ring and the first connection ring are disposed in a same layer, and located at a periphery of the first connection ring; the first transmission ring and the first connection ring are configured to transmit different voltage signals.

In an exemplary implementation, the display substrate further includes a light emitting structure layer located at a side of the circuit structure layer away from the base substrate, the light emitting structure layer includes a plurality of light emitting devices; three first pixel drive circuits in one circuit unit group are electrically connected to three light emitting devices in one-to-one correspondence; the light emitting structure layer includes an anode layer, the anode layer includes anodes of the plurality of light emitting devices and at least one second transmission ring; the second transmission ring is electrically connected to the first transmission ring, an orthographic projection of the second transmission ring on the base substrate is at least partially overlapped with an orthographic projection of the first transmission ring on the base substrate; the second transmission ring is located at a periphery of anodes of the three light emitting devices to which the three first pixel drive circuits of the circuit unit group are connected.

In an exemplary implementation, the display substrate further includes a light emitting structure layer located at a side of the circuit structure layer away from the base substrate, the light emitting structure layer includes a plurality of light emitting devices; wherein the circuit structure layer further includes a plurality of anode pads electrically connected to the first power supply line; an anode pad is located at a side of an anode of a light emitting device close to the base substrate, an orthographic projection of the anode pad on the base substrate includes an orthographic projection of an anode of at least one of the light emitting devices on the base substrate; a plurality of anode pads located on an inside of the first connection ring and the first connection ring are of an interconnected integral structure.

In an exemplary implementation, at least one of the anode pads is provided with a plurality of through holes arranged in an array.

In another aspect, the present disclosure provides a display apparatus, including the display substrate described above.

In yet another aspect, the present disclosure provides a preparation method of a display substrate, including: forming a circuit structure layer on the base substrate; the circuit structure layer includes at least a plurality of circuit units, at least one circuit unit includes a pixel drive circuit, and the pixel drive circuit includes a plurality of drive transistors; first electrodes of the plurality of drive transistors are connected to each other, second electrodes of the plurality of drive transistors are connected to each other, and gate electrodes of the plurality of drive transistors are connected to each other.

In yet another aspect, the present disclosure provides a display substrate, including: a base substrate and a circuit structure layer disposed on the base substrate, the circuit structure layer includes at least a plurality of circuit units, each circuit unit includes a pixel drive circuit, the pixel drive circuit includes a storage capacitor and a plurality of drive transistors; the storage capacitor includes a first plate and a second plate, the first plate serves as gate electrodes of the plurality of drive transistors; the second plate is located at a side of the first plate away from the base substrate; the second plate has a plurality of first openings, an orthographic projection of the first plate on the base substrate covers an orthographic projection of the plurality of first openings of the second plate on the base substrate; a second connection electrode located at a side of the second plate away from the base substrate is connected to the first plate through vias provided in the plurality of first openings.

In an exemplary implementation, within a single circuit unit, the first plate includes a plurality of first sub-plates, a single first sub-plate serves as a gate electrode of at least one drive transistor; the plurality of circuit units includes at least a first circuit unit, a second circuit unit, and a third circuit unit; an area of an orthographic projection of the first sub-plate in the third circuit unit on the base substrate is less than an area of an orthographic projection of the first sub-plate in the second circuit unit on the base substrate; the area of the orthographic projection of the first sub-plate in the third circuit unit on the base substrate is less than an area of an orthographic projection of the first sub-plate in the first circuit unit on the base substrate.

In an exemplary implementation, within a single circuit unit, the second plate has a plurality of first openings; the plurality of circuit units includes at least a first circuit unit, a second circuit unit, and a third circuit unit; an area of an orthographic projection of the first opening of the second plate within the third circuit unit on the base substrate that is greater than an area of an orthographic projection of the first opening of the second plate within the first circuit unit on the base substrate; the area of the orthographic projection of the first opening of the second plate within the third circuit unit on the base substrate is greater than an area of an orthographic projection of the first opening of the second plate within the second circuit unit on the base substrate.

In an exemplary implementation, the plurality of circuit units includes at least a first circuit unit, a second circuit unit, and a third circuit unit; a quantity of first openings of the second plate within the third circuit unit that is different from a quantity of first openings of the second plate within the first circuit unit; the quantity of first openings of the second plate within the first circuit unit is the same as the quantity of first openings of the second plate within the second circuit unit.

In an exemplary implementation, the pixel drive circuit in the first circuit unit is connected to a light emitting device emitting red light, the pixel drive circuit in the second circuit unit is connected to a light emitting device emitting green light, and the pixel drive circuit in the third circuit unit is connected to a light emitting device emitting blue light.

Other aspects of the present disclosure may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 is a schematic diagram of a planar structure of a display substrate.

FIG. 3 is a schematic partial cross-sectional view of a display substrate.

FIG. 4 is an equivalent circuit diagram of a pixel drive circuit according to at least one embodiment of the present disclosure.

FIG. 5 is a working timing diagram of a pixel drive circuit.

FIG. 6 is a partial top view of a display substrate according to at least one embodiment of the present disclosure.

FIG. 7 is a schematic diagram of a planar structure of the dashed region C in FIG. 6.

FIG. 8 is a schematic diagram of the display substrate after a semiconductor layer is formed in FIG. 7.

FIG. 9A is a schematic diagram of the display substrate after a first conductive layer is formed in FIG. 7.

FIG. 9B is a schematic diagram of the first conductive layer in FIG. 9A.

FIG. 9C is a schematic diagram of a first conductive layer in yet another implementation.

FIG. 10A is a schematic diagram of the display substrate after a second conductive layer is formed in FIG. 7.

FIG. 10B is a schematic diagram of the second conductive layer in FIG. 10A.

FIG. 11 is a schematic diagram of the display substrate after a third insulation layer is formed in FIG. 7.

FIG. 12A is a schematic diagram of the display substrate after a third conductive layer is formed in FIG. 7.

FIG. 12B is a schematic diagram of the third conductive layer in FIG. 12A.

FIG. 13 is a schematic diagram of a display substrate after a fifth insulation layer is formed in FIG. 7.

FIG. 14A is a schematic diagram of a display substrate after a fourth conductive layer is formed in FIG. 7.

FIG. 14B is a schematic diagram of a fourth conductive layer in FIG. 14A.

FIG. 15 is a schematic diagram of a display substrate after a sixth insulation layer is formed in FIG. 7.

FIG. 16 is a schematic view of an anode layer in FIG. 7.

FIG. 17A is a schematic diagram of a display substrate after a pixel definition layer is formed on the structure shown in FIG. 7.

FIG. 17B is a schematic diagram of the pixel definition layer in FIG. 17A.

FIG. 18 is a schematic diagram of a portion of a structure of the first circuit unit in FIG. 7.

### DETAILED DESCRIPTION

The embodiments of the present disclosure will be described below with reference to the drawings in detail. Implementation modes may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings. Scales of the drawings in the present disclosure may be used as a reference in actual processes, but are not limited thereto. For example, a width-length ratio of a channel, a thickness and spacing of a film, and a width and spacing of a signal line may be adjusted according to actual needs.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand meanings of the aforementioned terms in the present disclosure according to situations. Among them, an “electrical connection” includes a case where constituent elements are connected together through an element with a certain electrical effect. The “element with a certain electrical action” is not particularly limited as long as electrical signals between the connected constituent elements may be transmitted. Examples of the “element with the certain electrical effect” not only include electrodes and wirings, but also include switching elements such as transistors, resistors, inductors, capacitors, other elements with one or more functions, etc.

In the specification, a transistor refers to an element that at least includes three terminals, i.e., a gate electrode, a drain electrode, and a source electrode. The transistor has a channel region between the drain electrode (drain electrode terminal, drain area, or drain) and the source electrode (source electrode terminal, source area, or source), and a current can flow through the drain electrode, the channel region and the source electrode. In the specification, the channel region refers to a region through which a current mainly flows.

In the present specification, in order to distinguish between two electrodes of a transistor other than a gate, one electrode is referred to as a first electrode and the other electrode is referred to as a second electrode. For example, a first electrode may be a drain electrode and a second electrode may be a source electrode, or the first electrode may be a source electrode and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present specification, “about” refers to that a boundary is not defined so strictly and numerical values within a range of process and measurement errors are allowed.

In the present specification, “A extends along a B direction” means that A may include a main portion and a secondary portion connected to the main portion, the main portion is a line, a line segment, or a strip-shaped body, the main portion extends along the B direction, and a length of the main portion extending along the B direction is greater than a length of the secondary portion extending along another direction. In following description, “A extends along a B direction” means “a main body portion of A extends along a B direction”.

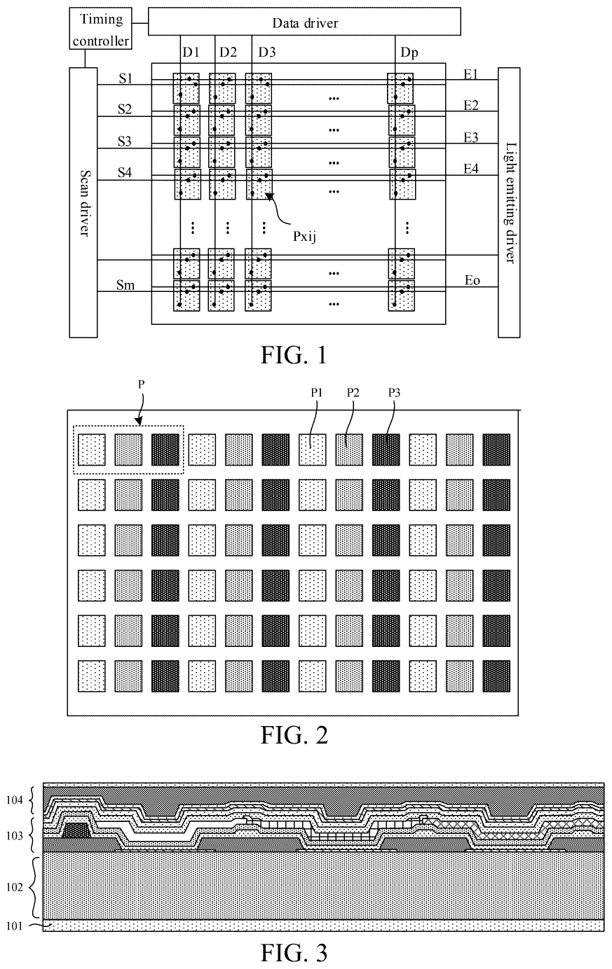

FIG. 1 is a schematic diagram of a structure of a display apparatus. As shown in FIG. 1, the display apparatus may include a timing controller, a data driver, a scan driver, a light emitting driver, and a pixel array. The timing controller may be connected with the data driver, the scan driver, and the light emitting driver, respectively. The data driver is respectively connected with a plurality of data lines (e.g., D1 to Dp), the scan driver is respectively connected with a plurality of scan lines (e.g., S1 to Sm), and the light emitting driver is respectively connected with a plurality of light emitting control lines (e.g., E1 to Eo). The pixel array may include a plurality of sub-pixels Pxij, wherein i and j may be natural numbers. At least one sub-pixel Pxij may include a circuit unit and a light emitting unit, wherein the circuit unit may include at least a pixel drive circuit which may be respectively connected with a scan line, a light emitting control line, and a data signal line, and the light emitting unit may include a light emitting device which may be electrically connected with the pixel drive circuit of the circuit unit.

In an exemplary implementation, the timing controller may provide the data driver with a gray scale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data lines D1, D2, D3 . . . and Dp using the gray-scale value and the control signal received from the timing controller. For example, the data driver may sample the grayscale value by using the clock signal and apply a data voltage corresponding to the grayscale value to the data lines D1 to Dp by taking a pixel row as a unit, wherein p may be a natural number. The scan driver may generate a scan signals to be provided to the scan lines S1, S2, S3, . . . , and Sm by receiving the clock signal and the scan start signal from the timing controller. For example, the scan driver may provide sequentially a scan signal with a turn-on level pulse to the scan lines S1 to Sm, where m may be a nature number. For example, the scan driver may be constructed in a form of a shift register and may generate a scan signal by sequentially transmitting a scan starting signal provided in a form of an on-level pulse to a next stage circuit under control of the clock signal. The light emitting driver may generate an emission signal to be provided to the light emitting signal lines E1, E2, E3, . . . , and Eo by receiving the clock signal and the emission stop signal from the timing controller. For example, the light emitting driver may provide sequentially the transmitting signal with an off-level pulse to the light emitting control lines E1 to Eo, where o may be a nature number. For example, the light emitting driver may be constructed in a form of the shift register, and generate an emission signal by sequentially transmitting an emission stopping signal provided in the form of an off-level pulse to a next-stage circuit under the control of the clock signal. In an exemplary implementation, the pixel array may be disposed on the display substrate.

FIG. 2 is a schematic diagram of a planar structure of a display substrate. In an exemplary embodiment, the display substrate may include a display region and a bezel region located on a periphery of the display region. As shown in FIG. 2, the display region of the display substrate may include a plurality of pixel units P arranged in a matrix. At least one of the pixel units P may include a first sub-pixel P1 emitting light in a first color, a second sub-pixel P2 emitting light in a second color, and a third sub-pixel P3 emitting light in a third color. Each sub-pixel may include a circuit unit and a light emitting unit. The circuit unit may at least include a pixel drive circuit, the pixel drive circuit may be connected to a scan signal line, a data line, and a light emitting control line respectively, and may be configured to receive a data voltage transmitted by the data line and output a corresponding current to the light emitting unit under control of the scan line and the light emitting control line. The light emitting unit may at least include a light emitting device, the light emitting device may be electrically connected with a pixel circuit of a sub-pixel where the light emitting device is located, and the light emitting device may be configured to emit light with corresponding brightness in response to a current output by the pixel circuit of the sub-pixel where the light emitting device is located.

In some examples, the pixel drive circuit may include multiple transistors and at least one capacitor. For example, the pixel drive circuit may be a circuit of a 3T1C, 4T1C, 5T1C, 5T2C, 6T1C, 7T1C, or 8T1C structure. Herein, in the above circuit structure, T refers to a thin film transistor, C refers to a capacitor, a number before T represents a quantity of thin film transistors in the circuit, and a number before C represents a quantity of capacitors in the circuit.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light.

In an exemplary implementation, a shape of a light emitting device may be a rectangle, a rhombus, a pentagon, or a hexagon. When one pixel unit includes three sub-pixels, light emitting devices of the three sub-pixels may be arranged side by side horizontally, side by side vertically, or in a manner like a Chinese character ““, etc. When one pixel unit includes four sub-pixels, light emitting devices of” the four sub-pixels may be arranged side by side horizontally, side by side vertically, or in a manner to form a square. The present disclosure is not limited here.

FIG. 3 is a schematic partial cross-sectional view of a display substrate. FIG. 3 illustrates a structure of three sub-pixels in the display substrate. In some examples, as shown in FIG. 3, in a direction perpendicular to the display substrate, the display region of the display substrate may include a base substrate 101, a circuit structure layer 102 disposed on the base substrate 101, a light emitting structure layer 103 disposed on a side of the circuit structure layer 102 away from the base substrate 101, and an encapsulation structure layer 104 disposed on a side of the light emitting structure layer 103 away from the base substrate 101. In some possible implementations, the display substrate may include another film layer, such as a touch structure layer, which is not limited here in the present disclosure.

In an exemplary implementation, the base substrate 101 may be a flexible base substrate, or may be a rigid base substrate. The circuit structure layer 102 may include multiple circuit units, a circuit unit may at least include a pixel drive circuit, and the pixel drive circuit may include multiple transistors and at least one capacitor. The light emitting structure layer 103 may include a plurality of light emitting units, and a light emitting unit may include at least a light emitting device. The encapsulation structure 104 layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is disposed between the first encapsulation layer and the third encapsulation layer to form a laminated structure of an inorganic material/an organic material/an inorganic material, which may ensure that external water vapor cannot enter the light emitting structure layer 103.

In an exemplary implementation, the light emitting device may be any of a Light Emitting Diode (LED), an Organic Light Emitting Diode (OLED), a Quantum dot Light Emitting Diode (QLED), a micro LED (including: a mini-LED or a micro-LED), and the like. For example, the light emitting device may be an OLED, and the light emitting device may emit red light, green light, blue light, or white light, etc. under drive of a pixel drive circuit corresponding to the light emitting element. A color of light emitted from the light emitting device may be determined as required. In some examples, the light emitting device may include an anode, a cathode, and an organic emitting layer disposed between the anode and the cathode. The anode of the light emitting device may be electrically connected with a corresponding pixel drive circuit, the organic emitting layer is connected with the anode, the cathode is connected with the organic emitting layer, and the organic emitting layer may emit light of a corresponding color under drive of the anode and the cathode. However, the present embodiment is not limited thereto.

In an exemplary implementation, the organic emitting layer may include: an Emitting Layer (EML) and any one or more of following: a Hole Injection Layer (HIL), a Hole Transport Layer (HTL), an Electron Block Layer (EBL), a Hole Block Layer (HBL), an Electron Transport Layer (ETL) and an Electron Injection Layer (EIL).

An exemplary embodiment of the present disclosure provides a display substrate, including a base substrate and a circuit structure layer disposed on the base substrate, wherein the circuit structure layer includes at least a plurality of circuit units, at least one circuit unit includes a pixel drive circuit, and the pixel drive circuit includes a plurality of drive transistors; first electrodes of the plurality of drive transistors are connected to each other, second electrodes of the plurality of drive transistors are connected to each other, and gate electrodes of the plurality of drive transistors are connected to each other.

In the display substrate according to an embodiment of the present disclosure, by providing a plurality of drive transistors in the pixel drive circuit, and connecting first electrodes, gate electrodes, and second electrodes of the plurality of drive transistors to each other, respectively, the drive current provided by the pixel drive circuit can be increased, thereby improving the display quality of the display substrate. In some examples, the display substrate of the present embodiment may be applied to a spliced display screen.

In some exemplary implementations, the pixel drive circuit may further include a storage capacitor. The storage capacitor includes a first plate and a second plate, and the second plate is located at a side of the first plate away from the base substrate; an orthographic projection of the first plate on the base substrate is at least partially overlapped with an orthographic projection of the second plate on the base substrate. The first plate includes a plurality of first sub-plates, and a single first sub-plate may serve as a gate electrode of at least one drive transistor. For example, the plurality of first sub-plates may be independently disposed and electrically connected by a second connection electrode, which may be located at a side of the second plate away from the base substrate. In this example, by providing a first sub-plate of the first plate and a gate electrode of the drive transistor as an integral structure, the electrical connection between the storage capacitor and the drive transistor can be ensured, and the size of the storage capacitor can be adjusted by adjusting the quantity or size of the first sub-plate.

In some exemplary implementations, the pixel drive circuit may further include a first initialization transistor and a threshold compensation transistor. A first electrode of the first initialization transistor is connected to a first initial signal line, and a second electrode of the first initialization transistor is connected to the gate electrodes of the plurality of drive transistors; a second electrode of the threshold compensation transistor is connected to the second electrodes of the plurality of drive transistors, and a first electrode of the threshold compensation transistor is connected to the gate electrodes of the plurality of drive transistors; the first initial transistor and the threshold compensation transistor are connected to the gate electrodes of the plurality of drive transistors through a second connection electrode. This example can realize all connectivity of the connection objects of the first node of the pixel drive circuit by the second connection electrode, which is beneficial to reasonable arrangement of transistors of the pixel drive circuit.

In some exemplary implementations, the plurality of drive transistors of the pixel drive circuit may be sequentially arranged along a second direction, the second plate of the storage capacitor extends along the second direction, and the second plate has a first end portion and a second end portion in the second direction. The first end portion and the second end portion of the second plate are respectively connected to a first power supply line; the first power supply line is located at a side of the second plate away from the base substrate. In the design of the present example, there are two lap positions between the second plate of the storage capacitor and the first power supply line, which can ensure the uniformity of transmitting a first voltage signal by the second plate.

In some exemplary implementations, the circuit structure layer may further include a data line connected to the pixel drive circuit and extending along the second direction, a first data transfer line extending along the first direction, and a second data transfer line extending along the second direction; the first direction intersects the second direction. The data line is connected to the second data transfer line through the first data transfer line; the first data transfer line is located at a side of the data line close to the base substrate, and the second data transfer line and the data line are disposed in a same layer. In this example, by providing the first data transfer line and the second data transfer line, a FIAA structure can be realized, which is beneficial to realizing a narrow bezel design.

In some exemplary implementations, the pixel drive circuit further includes a first initialization transistor, a first electrode of the first initialization transistor is connected to a first initialization signal line, and a second electrode of the first initialization transistor is connected to the gate electrodes of the plurality of drive transistors. The first initial signal line extends along the first direction, and the first initial signal line is connected to a first initial signal connection line extending along the second direction, and the first direction intersects the second direction. The first initial signal connection line is located at a side of the first initial signal line away from the base substrate. In this example, the first initial signal line and the first initial signal connection line are provided to be cross-connected to realize a net-like structure for transmitting a first initial signal, and ensure the transmission consistency of the first initial signal.

In some exemplary implementations, the pixel drive circuit further includes a second initialization transistor, a first electrode of the second initialization transistor is connected to a second initial signal line and a second electrode of the second initialization transistor is connected to a first electrode of a light emitting device to which the pixel drive circuit is connected; the second initial signal line extends along the first direction, and the second initial signal line is connected to a second initial signal connection line extending along the second direction; the second initial signal line and the first initial signal line are disposed in a same layer, and the second initial signal connection line and the first initial signal connection line are disposed in a same layer. In this example, the second initial signal line and the second initial signal connection line are provided to be cross-connected to realize a net-like structure for transmitting the second initial signal, and ensure the transmission consistency of the second initial signal. The display substrate in the present disclosure is illustrated with examples below through some exemplary embodiments.

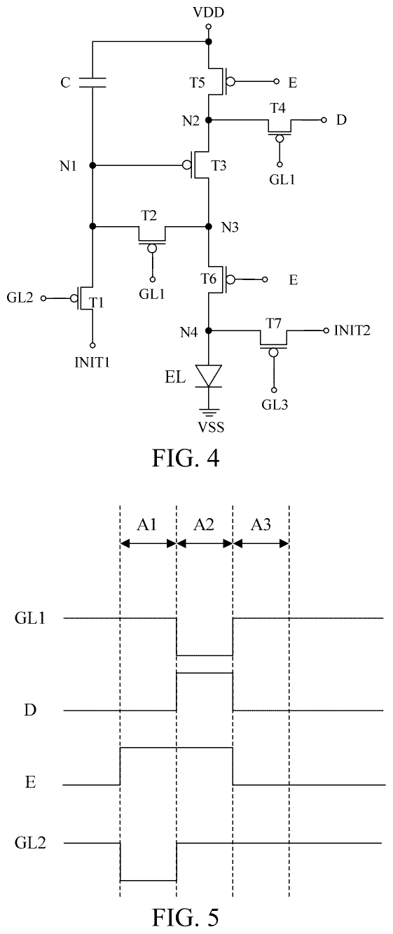

FIG. 4 is an equivalent circuit diagram of a pixel drive circuit according to at least one embodiment of the present disclosure. The pixel drive circuit of the present example may have a structure of 7T1C, and may include seven transistors (for example, a first transistor T1 to a seventh transistor T7) and one capacitor (for example, a storage capacitor C). The pixel drive circuit may be electrically connected to eight signal lines (including, for example, a first scan line GL 1, a second scan line GL 2, a third scan line GL 3, a light emitting control line E, a first initial signal line INIT 1, a second initial signal line INIT 2, a data line D, and a first power supply line VDD), respectively.

In an exemplary implementation, a first terminal of the storage capacitor C is connected to a first node N1, that is, the first terminal of the storage capacitor C is connected to a control electrode of the third transistor T3, and a second terminal of the storage capacitor C is connected to the first power supply line VDD.

A control electrode of the first transistor T1 is connected with the second scan line GL2, a first electrode of the first transistor T1 is connected with the first initial signal line INIT1, and a second electrode of the first transistor T1 is connected with the first node N1. When a scan signal with an on-level is applied to the second scan line GL2, the first transistor T1 transmits a first initialization voltage to the control electrode of the third transistor T3 so as to initialize a charge amount of the control electrode of the third transistor T3.

A control electrode of the second transistor T2 is connected with a first scan line GL1, a first electrode of the second transistor T2 is connected with a third node N3, and a second electrode of the second transistor T2 is connected with a first node N1. When a scan signal with an on-level is applied to the first scan line GL1, the second transistor T2 enables the control electrode of the third transistor T3 to be connected with the second electrode of the third transistor T3.

A control electrode of the third transistor T3 is connected with a first node N1, namely a control electrode of the third transistor T3 is connected with a first terminal of the storage capacitor C, a first electrode of the third transistor T3 is connected with a second node N2, and a second electrode of the third transistor T3 is connected with a third node N3. The third transistor T3 may be referred to as a drive transistor (DTFT), and the third transistor T3 determines an amount of a drive current flowing between the first power supply line VDD and the second power supply line VSS according to a potential difference between the control electrode and the first electrode of the third transistor T3. The first power supply line VDD may be configured to transmit a first voltage signal, the second power supply line VSS may be configured to transmit a second voltage signal, and the first voltage signal may be greater than the second voltage signal.

A control electrode of the fourth transistor T4 is connected with the first scan line GL1, a first electrode of the fourth transistor T4 is connected with the data line D, and a second electrode of the fourth transistor T4 is connected with the second node N2. The fourth transistor T4 may be referred to as a data writing transistor. When a scan signal with an on-level is applied to the first scan line GL1, the fourth transistor T4 enables a data voltage of the data line D to be input to the pixel drive circuit.

A control electrode of the fifth transistor T5 is connected to the light emitting signal line E, a first electrode of the fifth transistor T5 is connected to the first power supply line VDD, and the second electrode of the fifth transistor T5 is connected to the second node N2. A control electrode of the sixth transistor T6 is connected with a light emitting control line E, a first electrode of the sixth transistor T6 is connected with the third node N3, and a second electrode of the sixth transistor T6 is connected with the fourth node N4. The fifth transistor T5 and the sixth transistor T6 may be referred to as light emitting transistors. When a light emitting signal with an on-level is applied to the light emitting signal line E, the fifth transistor T5 and the sixth transistor T6 cause the light emitting device to emit light by forming a driving current path between the first power supply line VDD and the second power supply line VSS.

A control electrode of the seventh transistor T7 is connected with the third scan line GL3, a first electrode of the seventh transistor T7 is connected with the second initial signal line INIT2, and a second electrode of the seventh transistor T7 is connected with the fourth node N4. When a scan signal with an on-level is applied to the third scan line GL3, the seventh transistor T7 transmits a second initialization voltage to the first electrode of the light emitting device so as to initialize a charge amount accumulated in the first electrode of the light emitting device or release a charge amount accumulated in the first electrode of the light emitting device.

In an exemplary implementation, a second electrode of the light emitting device is connected to the second power supply line VSS, a signal of the second power supply line VSS is a low-level signal, and a signal of the first power supply line VDD is a high-level signal. The first scan line GL1 is a scan line in a pixel drive circuit in a current display row, and the second scan line GL2 is a scan line in a pixel drive circuit in a previous display row, that is, for the n-th display row, the first scan line GL1 is GL (n), and the second scan line GL2 is GL (n-1). The second scan line GL2 in the pixel drive circuit in the current display row and the first scan line GL1 in the pixel drive circuit in the previous display row are the same signal line, such that signal lines of a display panel can be reduced, so as to achieve a narrow bezel of the display panel. The third scan line GL3 may transmit the same signal as the first scan line GL1.

In an exemplary implementation mode, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In some examples, as shown in FIG. 4, the first node N1 may be connected to a second electrode of the first transistor T1, a second electrode of the second transistor T2, a control electrode of the third transistor T3, and a first terminal of the storage capacitor C, respectively. The second node N2 may be connected with a second electrode of the fifth transistor T5, a second electrode of a fourth transistor T4, and a first electrode of a third transistor T3, respectively. The third node N3 may be connected with a second electrode of the third transistor T3, a first electrode of the second transistor T2, and a first electrode of a sixth transistor T6 respectively. The fourth node N4 may be connected to a second electrode of the sixth transistor T6, a second electrode of the seventh transistor T7, and a first electrode of the light emitting device EL, respectively.

In an exemplary implementation, the light emitting device EL may be an organic light emitting diode (OLED), including a first electrode (anode), an organic light emitting layer and a second electrode (cathode) that are stacked.

FIG. 5 is a working timing diagram of a pixel drive circuit. An exemplary embodiment of the present disclosure will be described below through a working process of the pixel drive circuit exemplified in FIG. 4. The pixel drive circuit in FIG. 4 includes seven transistors (a first transistor T1 to a seventh transistor T7) and one storage capacitor C, and the seven transistors are all P-type transistors.

In an exemplary implementation, the working process of the pixel drive circuit may include following stages.

A first stage A1 is referred to as a reset stage. A signal of the second scan line GL 2 is a low-level signal, and signals of the first scan line GL 1 and the light emitting control line E are high-level signals. The signal of the second scan line GL2 is the low-level signal, so that the first transistor T1 is turned on, a signal of the first initial signal line INIT1 is provided to the first node N1 to initialize the storage capacitor C, thereby clearing an original data voltage in the storage capacitor. The signals of the first scan line GL1 and the light emitting signal line E are the high-level signals, so that the second transistor T2, the fourth transistor T4, the fifth transistor T5, the sixth transistor T6 and the seventh transistor T7 are turned off, therefore the light emitting device EL does not emit light in this stage.

A second stage A2 is referred to as a data writing stage or a threshold compensation stage. The signal of the first scan line GL1 is a low-level signal, signals of the second scan line GL2 and the light emitting control line E are high-level signals, and the data line outputs a data voltage. In this stage, the first end of the storage capacitor C is at a low-level, so the third transistor T3 is turned on. The signal of the first scan line GL1 is the low-level signal, so that the second transistor T2, the fourth transistor T4, and the seventh transistor T7 are turned on. The second transistor T2 and the fourth transistor T4 are turned on, so that the data voltage output by the data line D is provided to the first node N1 through the second node N2, the turned-on third transistor T3, the third node N3, and the turned-on second transistor T2, and the storage capacitor C is charged with a difference between the data voltage output by the data line D and a threshold voltage of the third transistor T3. A voltage of the first terminal (the first node N1) of the storage capacitor C is Vd-|Vth|, where Vd the data voltage output by the data line D, and Vth is the threshold voltage of the third transistor T3. The seventh transistor T7 is turned on, so that an initial voltage of the second initial signal line INIT2 is provided to the first electrode of the light emitting device EL to initialize (reset) the first electrode of the light emitting device EL and clear a pre-stored voltage therein, so as to complete initialization, thereby ensuring that the light emitting device EL does not emit light. A signal of the second scan line GL2 is a high-level signal, so that the first transistor T1 is turned off. The signal of the light emitting signal line E is the high-level signal, so that the fifth transistor T5 and the sixth transistor T6 are turned off.

A third stage A3 is referred to as a light emitting stage. A signal of the light emitting control line E is a low-level signal, and signals of the first scan line GL 1 and the second scan line GL 2 are high-level signals. The signal of the light emitting control line E is a low-level signal, so that the fifth transistor T5 and the sixth transistor T6 are turned on, and the power supply voltage output from the first power supply line VDD provides a driving voltage to the first electrode of the light emitting device EL through the fifth transistor T5, the third transistor T3 and the sixth transistor T6 which are turned on, to drive the light emitting device EL to emit light.

In a drive process of the pixel drive circuit, a drive current flowing through the third transistor T3 (drive transistor) is determined by a voltage difference between a gate electrode and the first electrode of the third transistor T3. Since the voltage of the first node N1 is Vdata-|Vth|, the drive current of the third transistor T3 is as follows.

$$I = K \times {( Vgs - Vth )}^{2} = K \times {[ ( Vdd - Vd + \vert Vth \vert ) - Vth ]}^{2} = K \times {[ Vdd - Vd ]}^{2}$$

Herein, I is the drive current flowing through the third transistor T3, i.e., a drive current for driving the light emitting device EL, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

It may be seen from the above formula that a current flowing through the light emitting element is independent of the threshold voltage of the third transistor T3. Therefore, the pixel drive circuit according to the present embodiment may better compensate the threshold voltage of the third transistor T3.

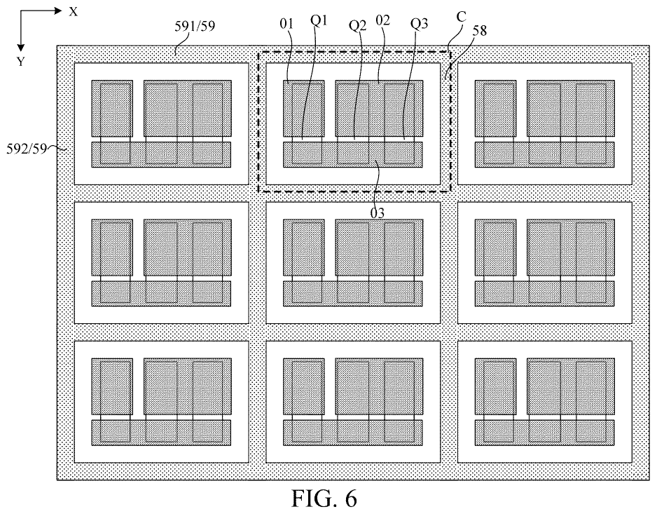

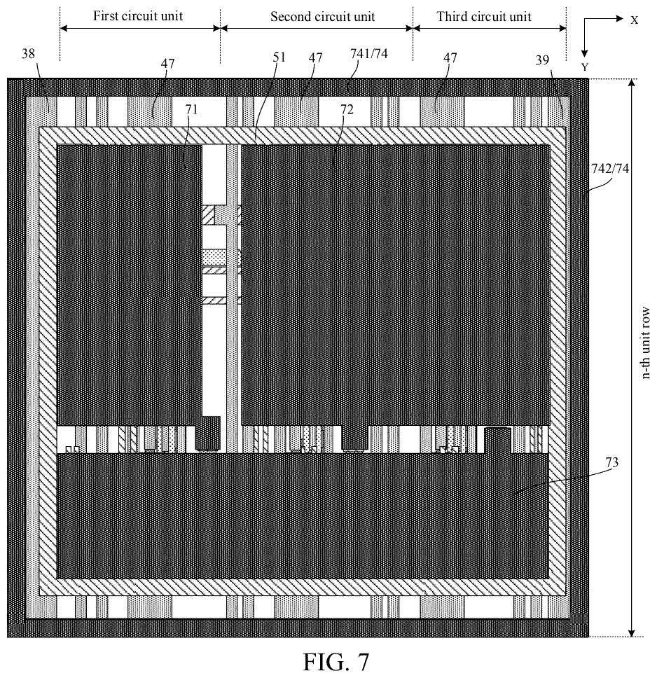

FIG. 6 is a partial top view of a display substrate according to at least one embodiment of the present disclosure, illustrating a plurality of pixel units, and one pixel unit may include three sub-pixels. In some examples, the display substrate may include a circuit structure layer and a light emitting structure layer sequentially disposed on the base substrate. The circuit structure layer may include a plurality of circuit units, the light emitting structure layer may include a plurality of light emitting units, at least one circuit unit may include a pixel drive circuit, and at least one light emitting unit may include a light emitting device. The light emitting device may include at least an anode, an organic emitting layer, and a cathode, and the anode of the light emitting device may be connected with a pixel drive circuit in a corresponding circuit unit.

The circuit unit described in the present disclosure refers to a region divided according to a pixel drive circuit; the light emitting unit described in the present disclosure refers to a region divided according to a light emitting device. In some examples, a position of an orthographic projection of a light emitting unit on the base substrate may correspond to a position of an orthographic projection of a circuit unit on the base substrate, or the position of the orthographic projection of the light emitting unit on the base substrate may not correspond to the position of the orthographic projection of the circuit unit on the base substrate.

In some examples, a plurality of circuit units sequentially disposed along a first direction X may be referred to as a unit row, and a plurality of circuit units sequentially disposed along a second direction Y may be referred to as a unit column, and the plurality of unit rows and the plurality of unit columns may constitute an array of circuit units arranged in an array. Wherein the first direction X intersects with the second direction Y, for example, the first direction X may be perpendicular to the second direction Y.

In some examples, as shown in FIG. 6, the circuit structure layer of the display substrate may further include a first transmission structure 59. The first transmission structure 59 may be configured to transmit the second voltage signal. The first transmission structure 59 may be formed by connecting a plurality of first transmission lines 591 extending along the first direction X and a plurality of second transmission lines 592 extending along the second direction Y. For example, the plurality of first transmission lines 591 and the plurality of second transmission lines 592 may be of an interconnected integral structure. The first transmission structure 59 may be a net-like structure located in the same conductive layer. However, the present embodiment is not limited thereto. In other examples, the first transmission lines 591 and the second transmission lines 592 may be located at different conductive layers; alternatively, at least one of a first transmission line 591 and a second transmission line 592 may be a double-layer trace structure.

In some examples, as shown in FIG. 6, the first transmission structure 59 may have a plurality of grids. Each grid may be formed by connecting and surrounding two adjacent second transmission lines 592 and two adjacent first transmission lines 591. One pixel unit (e.g., including three sub-pixels, each sub-pixel including a pixel drive circuit and a light emitting device connected to each other) may be provided within at least one grid. In some examples, as shown in FIG. 6, three pixel drive circuits in a single grid may include a first pixel drive circuit Q1, a second pixel drive circuit Q2, and a third pixel drive circuit Q3, the first pixel drive circuit Q1, the second pixel drive circuit Q2, and the third pixel drive circuit Q3 may be sequentially arranged along the first direction X, and three light emitting devices in a single grid may include a first light emitting device 01, a second light emitting device 02, and a third light emitting device 03. The first light emitting device 01 and the second light emitting device 02 may be sequentially arranged in the first direction X, and the third light emitting device 03 may be located at a same side of the first light emitting device 01 and the second light emitting device 02 in the second direction Y. The first light emitting device 01 may be connected to the first pixel drive circuit Q1, the second light emitting device 02 may be connected to the second pixel drive circuit Q2, and the third light emitting device 03 may be connected to the third pixel drive circuit Q3. For example, the first light emitting device 01 may be configured to emit red light, the second light emitting device 02 may be configured to emit green light, and the third light emitting device 03 may be configured to emit blue light. However, the present embodiment is not limited thereto.

In some examples, as shown in FIG. 6, the first transmission structure 59 may be a net-like structure located on a same conductive layer, and may include a plurality of first transmission rings 58. Two first transmission rings 58 adjacent along the first direction X or the second direction Y may be of an interconnected integral structure. A single first transmission ring 58 may surround to form a single grid. For example, an orthographic projection of the first transmission ring 58 on the base substrate may be a substantially rectangular ring. However, the present embodiment is not limited thereto. In other examples, the plurality of first transmission rings 58 of the first transmission structure 59 may be disposed independently of each other, and the plurality of first transmission rings 58 may be connected by electrodes or traces located in the remaining conductive layers.

In some examples, at least one pixel drive circuit may include a first transistor T1 as a first initialization transistor, a second transistor T2 as a compensation transistor, a third transistor T3 as a drive transistor, a fourth transistor T4 as a data writing transistor, a fifth transistor T5 as a first light emitting transistor and a sixth transistor T6 as a second light emitting transistor, a seventh transistor T7 as a second initialization transistor and a storage capacitor.

In some examples, in a direction perpendicular to the display substrate, the circuit structure layer may include a semiconductor layer, a first conductive layer, a second conductive layer, a third conductive layer, and a fourth conductive layer disposed on the base substrate sequentially. A first insulating layer may be provided between the semiconductor layer and the first conductive layer, a second insulating layer may be provided between the first conductive layer and the second conductive layer, a third insulating layer may be provided between the second conductive layer and the third conductive layer, a fourth insulating layer and a fifth insulating layer may be provided between the third conductive layer and the fourth conductive layer, and a sixth insulating layer may be provided on a side of the fourth conductive layer away from the base substrate. In some examples, the first insulation layer to the fourth insulation layer may be inorganic insulation layers, and the fifth insulation layer to the sixth insulation layer may be organic insulation layers. However, the present embodiment is not limited thereto. In some other examples, a buffer layer may be provided between the base substrate and the semiconductor layer. In some other examples, only the fifth insulation layer may be disposed between the third conductive layer and the fourth conductive layer.

FIG. 7 is a schematic diagram of a planar structure of the dashed region C in FIG. 6. FIG. 7 illustrates pixel drive circuits of three sub-pixels included in one pixel unit of the display substrate and anodes of light emitting devices to which the pixel drive circuits are connected.

In an exemplary embodiment, as shown in FIG. 7, the light emitting structure layer of the display substrate may include at least an anode layer, and the anode layer may include anodes of a plurality of light emitting devices (for example, including a first anode 71 of the first light emitting device 01, a second anode 72 of the second light emitting device 02, and a third anode 73 of the third light emitting device 03), and a second transmission structure. The second transmission structure may be a net-like structure located in the same conductive layer. The second transmission structure may include at least one second transmission ring 74. The second transmission ring 74 may be formed by connecting two adjacent third transmission lines 741 extending along the first direction X and two adjacent fourth transmission lines 742 extending along the second direction Y. For example, a plurality of third transmission lines 741 and a plurality of fourth transmission lines 742 may be of an interconnected integral structure. In some examples, adjacent second transmission rings 74 may be of an interconnected integral structure. However, the present embodiment is not limited thereto. In other examples, a plurality of second transmission rings may be disposed independently and connected by electrodes or traces of the remaining conductive layers.

In some examples, as shown in FIG. 7, the second transmission ring 74 of the second transmission structure may be configured to transmit the second voltage signal. The second transmission ring 74 may be electrically connected to the first transmission ring 58 of the first transmission structure 59 located in the circuit structure layer. In some examples, an orthographic projection of the second transmission ring 74 on the base substrate may be at least partially overlapped with an orthographic projection of the first transmission ring 58 on the base substrate, for example, the orthographic projection of the second transmission ring 74 on the base substrate may cover the orthographic projection of the first transmission ring 58 on the base substrate.

In some examples, as shown in FIG. 7, anodes of three light emitting devices may be provided within the second transmission ring 74, for example, including a first anode 71 of the first light emitting device 01, a second anode 72 of the second light emitting device 02, and a third anode 73 of the third light emitting device 03. The second transmission ring 74 surrounds the periphery of the three light emitting devices of one pixel unit.

In an exemplary embodiment, as shown in FIG. 7, the circuit structure layer of the display substrate may include a first connection ring 51, and an orthographic projection of the first connection ring 51 on the base substrate may be in a shape of a Chinese character “H”. The first connection ring 51 and the first transmission ring 58 of the first transmission structure 59 may be disposed in a same layer, and may be configured to transmit different voltage signals, for example, the first connection ring 51 may be configured to transmit a first voltage signal, and the first transmission ring 58 may be configured to transmit a second voltage signal. An orthographic projection of the first connection ring 51 on the base substrate may be located inside orthographic projections of the first transmission ring 58 and the second transmission ring 74 on the base substrate.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

“A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In the present disclosure, the shape of A refers to the shape of an orthographic projection of A on the base substrate. The dimension of A can characterize the size of A. For example, the shape of A is a rectangle, and the dimensions of A may include the length and width of the rectangle; the shape of A is a circle, and the dimensions of A may include the radius of the circle.

In an exemplary implementation, taking three circuit units in the n-th unit row (for example, a first circuit unit, a second circuit unit, and a third circuit unit sequentially disposed along the first direction X) as an example, the preparation process of the display substrate of this embodiment may include the following operations.

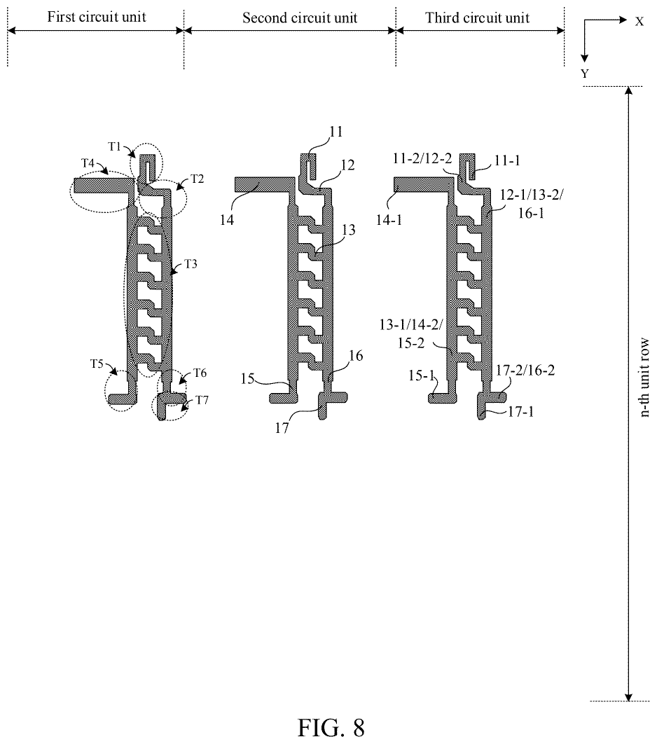

(1) A pattern of a semiconductor layer is formed. In an exemplary implementation, forming a pattern of a semiconductor layer may include depositing a semiconductor thin film on a base substrate and patterning the semiconductor thin film by a patterning process to form a semiconductor layer, as shown in FIG. 8. FIG. 8 is a schematic diagram of the display substrate after a semiconductor layer is formed in FIG. 7.

In an exemplary implementation, within one unit row, semiconductor layers in adjacent circuit units may be disposed independently of each other. The semiconductor layer of each circuit unit in the display substrate may include at least a first active layer 11 of the first transistor T1, a second active layer 12 of the second transistor T2, a plurality of third active layers 13 of a plurality of third transistors T3, a fourth active layer 14 of the fourth transistor T4, a fifth active layer 15 of the fifth transistor T5, a sixth active layer 16 of the sixth transistor T6, and a seventh active layer 17 of the seventh transistor T7, and the first active layer 11 to the seventh active layer 17 may be of an interconnected integral structure. FIG. 8 is illustrated by taking a case in which six third active layers are provided within a single circuit unit as an example, which is not limited in the present disclosure.

In an exemplary implementation, in a single circuit unit, the six third active layers 13 may be sequentially arranged along the second direction Y, and the six third active layers 13 may be of an interconnected integral structure. In a single circuit unit of the n-th unit row, the first active layer 11, the second active layer 12, and the fourth active layer 14 may be located at a side of the third active layer 13 close to the (n−1)-th unit row, that is, the first active layer 11, the second active layer 12, and the fourth active layer 14 may be located at a side of the third active layer 13 of the present circuit unit in an opposite direction of the second direction Y; the fifth to seventh active layers 15 to 17 may be located at a side of the third active layer 13 close to the (n+1)-th unit row, that is, the fifth to seventh active layers 15 to 17 may be located at a side of the third active layer 13 of the present circuit unit in the second direction Y.

In an exemplary implementation, in a single circuit unit, the second active layer 12 may be located on a side of the third active layer 13 of the present circuit unit in an opposite direction of the second direction Y, the first active layer 11 may be located on a side of the second active layer 12 of the present circuit unit in an opposite direction of the second direction Y, the fourth active layer 14 may be located on a side of the third active layer 13 of the present circuit unit in an opposite direction of the second direction Y, the fifth active layer 15 may be located on a side of the third active layer 13 of the present circuit unit in the second direction Y, the sixth active layer 16 may be located on a side of the third active layer 13 of the present circuit unit in the second direction Y, and the seventh active layer 17 may be located on a side of the sixth active layer 16 of the present circuit unit in the second direction Y.

In an exemplary implementation, within a single circuit unit, the fourth active layer 14 may be located on a side of the first active layer 11 and the second active layer 12 of the present circuit unit in the first direction X (such as a side in an opposite direction of the first direction X), and the sixth active layer 16 and the seventh active layer 17 may be located on another side of the fifth active layer 15 of the present circuit unit in the first direction X (such as a side in the first direction X).

In an exemplary implementation, the first active layer 11 may be in an “n” shape, the second active layer 12, the fourth active layer 14, the fifth active layer 15, and the seventh active layer 17 may be in an “L” shape, the third active layer 13 may be in an “Z” shape, the sixth active layer 16 may be in an “I” shape.

In an exemplary implementation, an active layer of each transistor may include a first region, a second region, and a channel region located between the first region and the second region. In an exemplary implementation, the first regions 13-1 of the six third active layers 13 in a single circuit unit may be directly connected, and the second regions 13-2 of the six third active layers 13 may be directly connected, so that the six third active layers 13 are of an interconnected integral structure, and the channel regions of the six third active layers may not be connected, for example, the channel regions of the six third active layers 13 may be parallel to each other. The second region 11-2 of the first active layer 11 and the second region 12-2 of the second active layer 12 may be directly connected, and the second region 11-2 of the first active layer 11 may serve as the second region 12-2 of the second active layer 12. The first regions 13-1 of the six third active layers 13, the second region 14-2 of the fourth active layer 14, and the second region 15-2 of the fifth active layer 15 may be directly connected, and the integral structure of the first regions 13-1 of the six third active layers 13 may simultaneously serve as the second region 14-2 of the fourth active layer 14 and the second region 15-2 of the fifth active layer 15. The first region 12-1 of the second active layer 12, the integral structure of the second regions 13-2 of the six third active layers 13, and the first region 16-1 of the sixth active layer 16 may be directly connected, and the integral structure of the second regions 13-2 of the six third active layers 13 may simultaneously serve as the first region 12-1 of the second active layer 12 and the first region 16-1 of the sixth active layer 16 to constitute the third node N3 of the pixel drive circuit. A second region 16-2 of the sixth active layer 16 and a second region 17-2 of the seventh active layer 17 may be connected directly, and the second region 16-2 of the sixth active layer 16 may serve as the second region 17-2 of the seventh active layer 17, forming a fourth node N4 of the pixel drive circuit. A first region 11-1 of the first active layer 11, a first region 14-1 of the fourth active layer 14, a first region 15-1 of the fifth active layer 15, and a first region 17-1 of the seventh active layer 17 may be individually disposed.

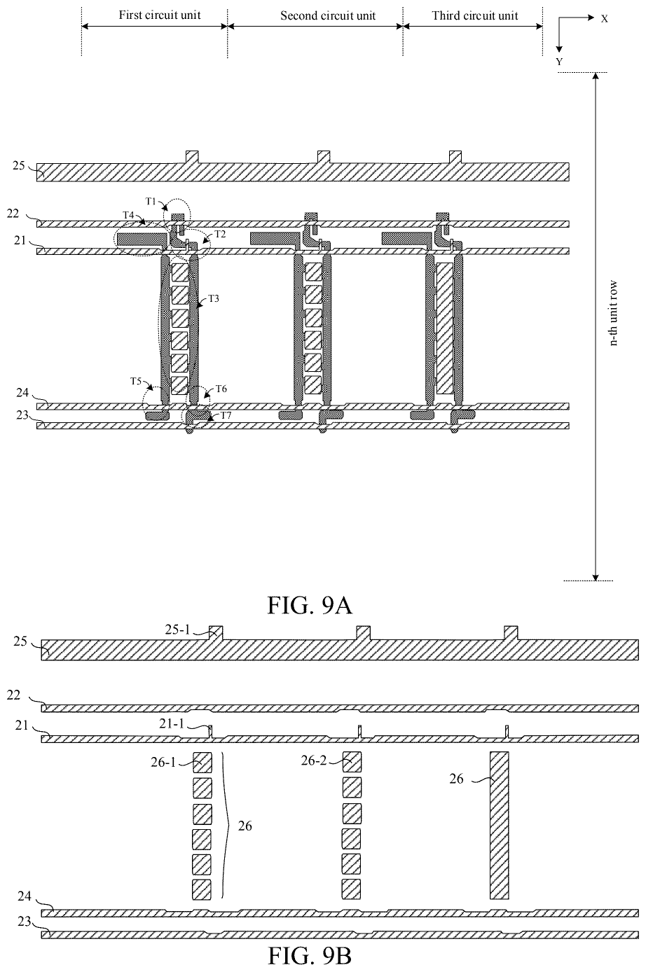

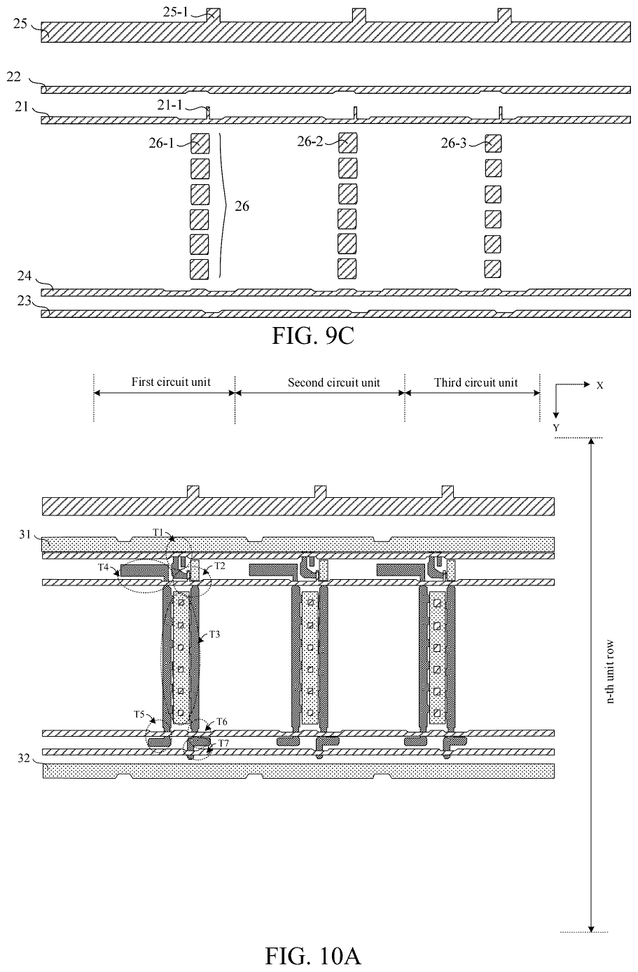

(2) A pattern of a first conductive layer is formed. In an exemplary implementation, forming the pattern of the first conductive layer may include: depositing sequentially a first insulating thin film and a first conductive thin film on the base substrate on which the aforementioned pattern is formed, and patterning the first conductive thin film by a patterning process to form a first insulating layer and the pattern of the first conductive layer arranged on the first insulating layer, as shown in FIGS. 9A, 9B and 9C. FIG. 9A is a schematic diagram of the display substrate after a first conductive layer is formed in FIG. 7; FIG. 9B is a schematic diagram of the first conductive layer in FIG. 9A. In an exemplary implementation, the first conductive layer may be referred to as a first gate metal (GATE1) layer.

In an exemplary implementation, the pattern of the first conductive layer of each circuit unit in the display substrate at least includes: a first scan line 21, a second scan line 22, a third scan line 23, a light emitting control line 24, a first data transfer line 25 and a first plate 26 of a first storage capacitor. The first plate 26 of the storage capacitor may simultaneously serve as a lower plate of the storage capacitor and gate electrodes of the six third transistors T3.

In an exemplary implementation, in at least one circuit unit (such as the first circuit unit and the second circuit unit shown in FIG. 9A), the first plate 26 of the storage capacitor may include a plurality (for example, six) of first sub-plates separated from each other, the quantity of the first sub-plates may be equal to the quantity of the third active layers, and a single first sub-plate may serve as a gate electrode of a single third transistor T3. Taking the first circuit unit illustrated in FIG. 9A as an example, the first sub-plate 26-1 may be in a shape of a rectangle, corners of the rectangle may be provided with chamfers. The plurality of first sub-plates 26-1 separated from each other may be sequentially arranged along the second direction Y, an orthographic projection of a single first sub-plate 26-1 on the base substrate is at least partially overlapped with an orthographic projection of the third active layer 13 of a single third transistor T3 on the base substrate, and the shapes and sizes of the six first sub-plates 26-1 may be the same. However, the present embodiment is not limited thereto. In other examples, the quantity of first sub-plates may be less than the quantity of third active layers, for example, at least one first sub-plate may simultaneously serve as gate electrodes of at least two third transistors. In other examples, some of the six first sub-plates 26-1 may be different in shape or size. A plurality of first sub-plates 26-2 of the second circuit unit in FIG. 9A can be referred to the above description of the first sub-plates 26-1 in the first circuit unit, and will not be repeatedly described here.

In an exemplary implementation, the shape or size of the first sub-plate 26-2 located in the second circuit unit may be the same as the shape or size of the first sub-plate 26-1 in the first circuit unit aligned along the first direction X, and the quantity of the first sub-plates 26-2 in the second circuit unit may be the same as the quantity of the first sub-plates 26-1 in the first circuit unit, which is not limited in the present disclosure.

In an exemplary implementation, in at least one circuit unit (such as the third circuit unit in FIG. 9A), the six first sub-plates of the first plate 26 may be provided as an interconnected integral structure.

In some examples, by adjusting the quantity of first sub-plates of the first plate 26, an overlapping area between the first plate 26 and a subsequently formed second plate can be controlled, thereby adjusting the size of the storage capacitor in the pixel drive circuit. In some examples, a first light emitting device connected to the pixel drive circuit in the first circuit unit emits red light, a second light emitting device connected to the pixel drive circuit in the second circuit unit emits green light, and a third light emitting device connected to the pixel drive circuit in the third circuit unit emits blue light. With the provision method of the first plate of the present example, the differentiated design of the storage capacitors of the pixel drive circuits corresponding to the third light emitting device emitting blue light and the first light emitting device emitting red light, and the second light emitting device emitting green light can be satisfied. For example, the capacitance of the storage capacitor of the pixel drive circuit corresponding to the third light emitting device emitting blue light may be larger than the capacitance of the storage capacitor of the pixel drive circuit corresponding to the first light emitting device and the second light emitting device that emit red light or green light. However, the present embodiment is not limited thereto. In other examples, the first plates of the storage capacitors of a plurality of pixel drive circuits may be of the same design.

In an exemplary implementation mode, the first scan line 21 may be in a shape of a line in which a main portion extends along the first direction X, may be located at a side of the first plate 26 in an opposite direction of the second direction Y, and a region where the first scan line 21 overlaps with the fourth active layer may serve as a gate electrode of the fourth transistor T4.

In an exemplary implementation, a first scan protrusion 21-1 may be provided on a side of the first scan line 21 away from the first plate 26, the first scan protrusion 21-1 may be provided in each circuit unit, a first end of the first scan protrusion 21-1 is connected to the first scan line 21, and a second end of the first scan protrusion 21-1 extends toward a side away from the first plate 26. The first scan line 21 and a plurality of first scan protrusions 21-1 may be of an interconnected integral structure. A region where the first scan line 21, the first scan protrusion 21-1 and the second active layer overlap may serve as a gate electrode of the second transistor T2 with a double-gate structure.

In an exemplary implementation, the second scan line 22 may be in a shape of a line in which a main body portion extends along the first direction X, may be located at a side of the first scan line 21 in an opposite direction of the second direction Y, and a region where the second scan line 22 overlaps the first active layer may serve as a gate electrode of the first transistor T1 with a double-gate structure.

In an exemplary implementation, the light emitting control line 24 may be in a shape of a line in which a main body portion extends along the first direction X, may be located at a side of the first plate 26 in the second direction Y, a region where the light emitting control line 24 overlaps the fifth active layer may serve as a gate electrode of the fifth transistor T5, and a region where the light emitting control line 24 overlaps the sixth active layer may serve as a gate electrode of the sixth transistor T6.

In an exemplary implementation, the third scan line 23 may be in a shape of a line in which a main body portion extends along the first direction X, may be located at a side of the light emitting control line 24 in the second direction Y, and a region where the third scan line 23 overlaps the seventh active layer may serve as a gate electrode of the seventh transistor T7.

In an exemplary implementation, the first data transfer line 25 may be in a shape of a line in which a main body portion extends along the first direction X, and may be located at a side of the second scan line 22 in an opposite direction of the second direction Y. An orthographic projection of the first data transfer line 25 on the base substrate and an orthographic projection of the semiconductor layer on the base substrate may not overlap.

In an exemplary implementation, a first data transfer portion 25-1 may be provided on a side of the first data transfer line 25 away from the first plate 26, the first data transfer portion 25-1 may be provided in each circuit unit, a first end of the first data transfer portion 25-1 may be connected to the first data transfer line 25, a second end of the first data transfer portion 25-1 may extend to a side away from the second scan line 22, and the first data transfer portion 25-1 may be configured to be connected to a subsequently formed data line or a second data transfer line. The first data transfer line 25 and a plurality of first data transfer portions 25-1 may be of an interconnected integral structure.

FIG. 9C is a schematic diagram of a first conductive layer in yet another implementation. FIG. 9C is different from FIG. 9B in that the structure of the first sub-plate in the third circuit unit is different. As shown in FIG. 9C, the third circuit unit may be provided with six first sub-plates 26-3, the plurality of first sub-plates 26-3 separated from each other may be sequentially arranged along the second direction Y, an orthographic projection of a single first sub-plate 26-3 on the base substrate is at least partially overlapped with an orthographic projection of the third active layer 13 of a single third transistor T3 on the base substrate, and the shapes and sizes of the six first sub-plates 26-3 may be the same. A first sub-plate 26-3 may be in a shape of a rectangle, corners of the rectangle may be provided with chamfers. In other examples, some of the six first sub-plates 26-3 may be different in shape or size. The remaining structures in FIG. 9C may be described above with reference to FIG. 9B, and will not be repeated herein.

In some examples, as shown in FIG. 9C, the shape of the first sub-plate 26-3 in the third circuit unit is the same as the shape of the first sub-plate 26-1 in the first circuit unit and the shape of the first sub-plate 26-2 in the second circuit unit, the size of the first sub-plate 26-3 in the third circuit unit may be smaller than the size of the first sub-plate 26-1 in the first circuit unit, and the size of the first sub-plate 26-3 in the third circuit unit may be smaller than the size of the first sub-plate 26-2 in the second circuit unit. In this example, an area of an orthographic projection of the first sub-plate 26-3 located in the third circuit unit on the base substrate may be smaller than an area of an orthographic projection of the first sub-plate 26-1 located in the first circuit unit on the base substrate, and the area of the orthographic projection of the first sub-plate 26-3 located in the third circuit unit on the base substrate may be smaller than an area of an orthographic projection of the first sub-plate 26-2 located in the second circuit unit on the base substrate. However, the present embodiment is not limited thereto.

In this example, by adjusting an area of an orthographic projection of the first sub-plate of the first plate 26, the overlapping area between the first plate 26 and a subsequently formed second plate can be controlled, thereby adjusting the size of the storage capacitor in the pixel drive circuit. In some examples, a first light emitting device connected to the pixel drive circuit in the first circuit unit emits red light, a second light emitting device connected to the pixel drive circuit in the second circuit unit emits green light, and a third light emitting device connected to the pixel drive circuit in the third circuit unit emits blue light. With the provision method of the first plate of the present example, the differentiated design of the storage capacitors of the pixel drive circuits corresponding to the third light emitting device emitting blue light and the first light emitting device emitting red light, and the second light emitting device emitting green light can be satisfied.

In other examples, the shape and the quantity of the first sub-plates 26-3 of the third circuit unit may be different from the shape and the quantity of the first sub-plates 26-1 of the first circuit unit, and the shape and the quantity of the first sub-plates 26-3 of the third circuit unit may be different from the shape and the quantity of the first sub-plates 26-2 of the second circuit unit, which is not limited in the present disclosure.

In an exemplary implementation mode, after the pattern of the first conductive layer is formed, a conductive processing may be performed on the semiconductor layer by using the first conductive layer as a shield, the semiconductor layer in a region shielded by the first conductive layer forms channel regions of the first transistor T1 to the seventh transistor T7, and the semiconductor layer in a region not shielded by the first conductive layer is made to be conductive, that is, first regions and second regions of the first active layer to the seventh active layer are all made to be conductive.

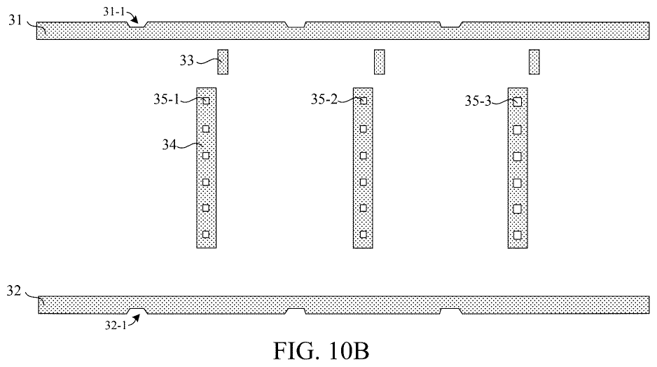

(3) A pattern of a second conductive layer is formed. In an exemplary implementation, forming the pattern of the second conductive layer may include sequentially depositing a second insulating thin film and a second conductive thin film on the base substrate on which the aforementioned pattern is formed, patterning the second conductive thin film by a patterning process to form a second insulating layer covering the first conductive layer, and the pattern of the second conductive layer disposed on the second insulating layer, as shown in FIGS. 10A and 10B, FIG. 10A is a schematic diagram of the display substrate after a second conductive layer is formed in FIG. 7, and FIG. 10B is a schematic diagram of the second conductive layer in FIG. 10A. In an exemplary implementation, the second conductive layer may be referred to as a second gate metal (GATE2) layer.

In an exemplary implementation, the pattern of the second conductive layer of each circuit unit in the display substrate includes at least a first initial signal line 31, a second initial signal line 32, a shielding electrode 33, and a second plate 34.

In an exemplary implementation, a contour of the second plate 34 may be in a shape of a rectangle, corners of the rectangle may be provided with chamfers, a long direction of the shape of the rectangle may be the second direction Y, the second plate 34 may be located at a side of the first scan line 21 in the second direction Y, and the second plate 34 may be located at a side of the light emitting control line 24 in an opposite direction of the second direction Y, that is, the second plate 34 may be located between the first scan line 21 and the light emitting control line 24 of the present circuit unit, an end of the second plate 34 close to the first scan line 21 may be referred to as a first end portion, and an end of the second plate 34 close to the light emitting control line 24 may be referred to as a second end portion. An orthographic projection of the second plate 34 on the base substrate is at least overlapped with an orthographic projection of the first plate 26 on the base substrate. The second plate 34 may serve as an upper plate of the storage capacitor, and the first plate 26 and the second plate 34 constitute the storage capacitor of the pixel drive circuit.

In an exemplary implementation, a plurality (e.g., six) of first openings are provided on the second plate 34 of each circuit unit. Taking the first circuit unit shown in FIG. 10A as an example, the plurality of first openings 35-1 may be sequentially arranged along the second direction Y, and may be located in the middle of the second plate 34 along the first direction X, a first opening 35-1 may in a shape of a rectangle, and the plurality of first openings 35-1 may be provided in one-to-one correspondence with the plurality of first sub-plates 26-1 of the first plate 26. The first opening 35-1 exposes the second insulating layer covering the first sub-plate 26-1, and an orthographic projection of the first sub-plate 26-1 on the base substrate includes an orthographic projection of the first opening 35-1 on the base substrate, and six first openings 35-1 may be the same in size and shape. However, the present embodiment is not limited thereto. In other examples, some of the six first openings 35-1 may be different in shape or size. In an exemplary implementation, the first opening 35-1 is configured to accommodate a subsequently formed eighth via, the eighth via of the first circuit unit is located in the first opening 35-1 and exposes the first sub-plate 26-1, so that the subsequently formed second connection electrode is connected to the first sub-plate 26-1. A plurality of first openings 35-2 of the second circuit unit in FIG. 10A may be referred to the above description of the first openings 35-1 in the first circuit unit, which will not be repeated here.

In an exemplary implementation, the shape or size of the first opening 35-2 located in the second circuit unit may be the same as the shape or size of the first opening 35-1 in the first circuit unit aligned in the first direction X, and the quantity of the first openings 35-2 in the second circuit unit may be the same as the quantity of the first openings 35-1 in the first circuit unit, which is not limited in the present disclosure.

In an exemplary implementation, as shown in FIG. 10A, in the third circuit unit, the size of the first opening 35-3 provided on the second plate 34 may be greater than or equal to the size of the first opening in the first circuit unit or the second circuit unit. Since the plurality of first sub-plates in the third circuit unit are of an interconnected integral structure, by adjusting the size of the first opening 35-3 on the second plate 34, the overlapping area between the first plate 26 and the second plate 34 can be adjusted, which facilitates the obtaining of a suitable value of the size of the storage capacitor. The quantity and intersection of the first sub-plates and the size of the first opening 35-3 of the second plate 34 may be set as necessary, which is not limited in the present disclosure.

In an exemplary implementation, the first initial signal line 31 and the second initial signal line 32 may be in a shape of a line in which a main body portion extends along the first direction X, the first initial signal line 31 may be located at a side of the second plate 34 in an opposite direction of the second direction Y, and the second initial signal line 32 may be located on a side of the second plate 34 in the second direction Y. The second initial signal line 32 may be located at a side of the third scan line 23 in the second direction Y.

In an exemplary implementation, the first initial signal line 31 may be located at a side of the second scan line 22 in an opposite direction of the second direction Y, and the first initial signal line 31 may be located at a side of the first data transfer line 25 in the second direction Y, that is, the first initial signal line 31 may be located between the second scan line 22 and the first data transfer line 25. A side of the first initial signal line 31 close to the first data transfer line 25 may be provided with a first notch 31-1, and the first notch 31-1 may expose a surface of the second insulating layer. An orthographic projection of the subsequently formed data line on the base substrate and an orthographic projection of the first initial signal line 31 on the base substrate may overlap at the first notch 31-1. Since an area of the first initial signal line 31 at the first notch 31-1 is small, the overlapping area of the first initial signal line 31 and the data line is also small, so that the coupling capacitance between the first initial signal line 31 and the data line can be reduced.

In an exemplary implementation, the second initial signal line 32 may be located at a side of the third scan line 23 in the second direction Y. A side of the second initial signal line 32 away from the third scan line 23 may be provided with a second notch 32-1, and the second notch 32-1 may expose a surface of the second insulating layer. An orthographic projection of the subsequently formed data line on the base substrate and an orthographic projection of the second initial signal line 32 on the base substrate may overlap at the second notch 32-1. Since an area of the second initial signal line 32 at the second notch 32-1 is small, the overlapping area of the second initial signal line 32 and the data line is also small, so that the coupling capacitance between the second initial signal line 32 and the data line can be reduced.

In an exemplary implementation, an orthographic projection of the first initial signal line 31 on the base substrate may be at least partially overlapped with an orthographic projection of the first active layer between two gate electrodes of the first transistor T1 on the base substrate, which may play a role in shielding the influence of data voltage jumps on the first transistor T1, avoiding the data voltage jumps from affecting the normal operation of the pixel drive circuit, and improving the display effect. In an exemplary implementation, the shielding electrode 33 may in a shape of a rectangle, may be located at a side of the first initial signal line 31 close to the second plate 34, and the shielding electrode 33 may be provided in each circuit unit. An orthographic projection of the shielding electrode 33 on the base substrate may be at least partially overlapped with an orthographic projection of a conductivized region between channel regions of the second active layer of the second transistor T2 on the base substrate. For example, an orthographic projection of the fifth shielding electrode 33 on the base substrate may be at least partially overlapped with an orthographic projection of the second active layer between two gate electrodes of the second transistor T2 in the present circuit unit on the base substrate. In the exemplary embodiment, the shielding electrode 33 is configured to protect the channel region of the second transistor T2 from interference, e.g., to shield the effect of data voltage jumps on the second transistor T2, to avoid the data voltage jumps from affecting the normal operation of the pixel drive circuit, and to improve the display effect.

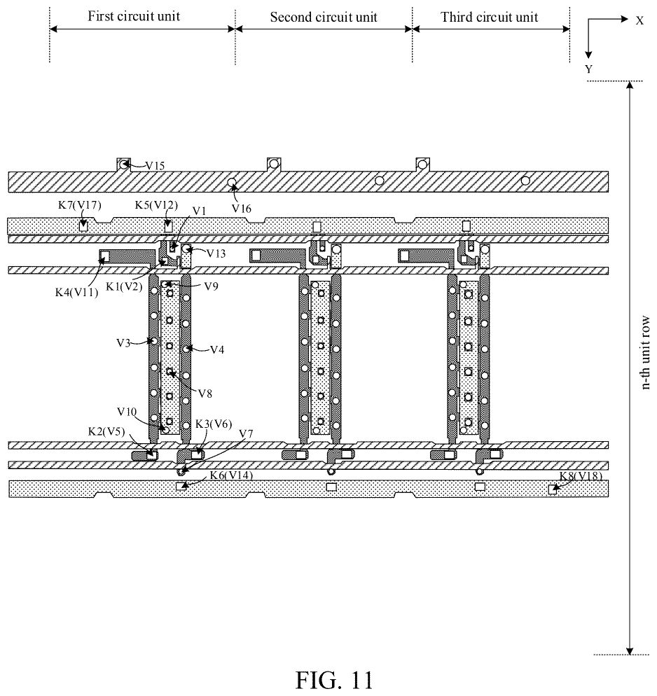

(4) A pattern of a third insulating layer is formed. In an exemplary implementation, forming a pattern of a third insulating layer may include: depositing a third insulating thin film on the base substrate on which the aforementioned pattern is formed, patterning the third insulating thin film by a patterning process to form a third insulating layer, and the third insulating layer in each circuit unit may be provided with a plurality of vias, as shown in FIG. 11. FIG. 11 is a schematic diagram of the display substrate after a third insulation layer is formed in FIG. 7.

In an exemplary implementation, the plurality of vias of each circuit unit in the display substrate may include at least a first via V1, a first hole group K1, a third via V3, a fourth via V4, a second hole group K2, a third hole group K3, a seventh via V7, an eighth via V8, a ninth via V9, a tenth via V10, a fourth hole group K4, a fifth hole group K5, a thirteenth via V13, a sixth hole group K6, a fifteenth via V15, and a sixteenth via V16.

In an exemplary implementation mode, an orthographic projection of the first via V1 on the base substrate is within a range of an orthographic projection of a first region of a first active layer on the base substrate, the third insulation layer, the second insulation layer and the first insulation layer within the first via V1 is etched away to expose a surface of the first region of the first active layer, and the first via V1 is configured to enable a subsequently formed first connection electrode to be connected with the first region of the first active layer through the via.

In an exemplary implementation, an orthographic projection of the first hole group K1 on the base substrate is within a range of an orthographic projection of a second region of the first active layer (also a second region of the second active layer) on the base substrate, the first hole group K1 may include at least two second vias V2, the third insulating layer, the second insulating layer and the first insulating layer within the second vias V2 are etched away to expose a surface of the second region of the first active layer (also the second region of the second active layer), and the first hole group K1 is configured to enable a subsequently formed second connection electrode to be connected with the second region of the first active layer (also the second region of the second active layer) through the via group.

In an exemplary implementation, The at least two second vias V2 may be arranged in an array, for example, the first hole group K1 may include two second vias V2 distributed in one row and two columns, a row direction may be the first direction, and a column direction may be the second direction. The use of the design of the hole group can make the contact area between a subsequently formed second connection electrode and the second region of the first active layer (also the second region of the second active layer) larger, with more contact points, and the signal transmission effect between the two is better and the connection is tighter. In other implementations, the at least two second vias V2 may be distributed in other ways or may be irregularly distributed, which is not limited in the present disclosure.

In an exemplary implementation, an orthographic projection of the third via V3 on the base substrate is within a range of an orthographic projection of a first region of the third active layer (also a second region of the fourth active layer and a second region of the fifth active layer) on the base substrate, the third insulating layer, the second insulating layer and the first insulating layer within the third via V3 are etched away to expose a surface of the first region of the third active layer, and the third via V3 is configured to enable a subsequently formed third connection electrode to be connected with the first region of the third active layer (also the second region of the fourth active layer and the second region of the fifth active layer) through the via. Within a single circuit unit, the quantity of third vias V3 may be equal to the quantity of third transistors.

In an exemplary implementation, an orthographic projection of the fourth via V4 on the base substrate is within a range of an orthographic projection of a second region of the third active layer (also a first region of the second active layer and a first region of the sixth active layer) on the base substrate, the third insulating layer, the second insulating layer, and the first insulating layer within the fourth via V4 are etched away to expose a surface of the second region of the third active layer, and the fourth via V4 is configured to enable a subsequently formed fourth connection electrode to be connected with the second region of the third active layer (also the first region of the second active layer and the first region of the sixth active layer) through the via. Within a single circuit unit, the quantity of fourth vias V4 may be equal to the quantity of third transistors.

In an exemplary implementation, an orthographic projection of the second hole group K2 on the base substrate is within a range of an orthographic projection of a first region of the fifth active layer on the base substrate, the second hole group K2 may include at least two fifth vias V5, the third insulating layer, the second insulating layer, and the first insulating layer within the fifth vias V5 are etched away to expose a surface of the first region of the fifth active layer, and the second hole group K2 is configured to enable a subsequently formed first power supply line to be connected with the first region of the fifth active layer through the via group to enable a first electrode of the fifth transistor to receive a first voltage signal.

In an exemplary implementation, the at least two fifth vias V5 may be arranged in an array, for example, the second hole group K2 may include two fifth vias V5 distributed in one row and two columns. In other implementations, the at least two fifth vias V5 may be distributed in other ways or may be irregularly distributed, which is not limited in the present disclosure.

In an exemplary implementation, an orthographic projection of the third hole group K3 on the base substrate is within a range of an orthographic projection of a second region of the sixth active layer (also a second region of the seventh active layer) on the base substrate, the third hole group K3 may include at least two sixth vias V6, the third insulating layer, the second insulating layer and the first insulating layer within the sixth vias V6 are etched away to expose a surface of the second region of the sixth active layer (also the second region of the seventh active layer), and the third hole group K3 is configured to enable a subsequently formed fifth connection electrode to be connected with the second region of the sixth active layer (also the second region of the seventh active layer) through the via group.

In an exemplary implementation, the at least two sixth vias V6 may be arranged in an array, for example, the third hole group K3 may include two sixth vias V6 distributed in one row and two columns. In other implementations, the at least two sixth vias V6 may be distributed in other ways or may be irregularly distributed, which is not limited in the present disclosure.

In an exemplary implementation, an orthographic projection of the seventh via V7 on the base substrate is within a range of an orthographic projection of a first region of the seventh active layer on the base substrate, the third insulating layer, the second insulating layer, and the first insulating layer within the seventh via V7 are etched away to expose a surface of the first region of the seventh active layer, and the seventh via V7 is configured to enable a subsequently formed sixth connection electrode to be connected with the first region of the seventh active layer through the via.

In an exemplary implementation, an orthographic projection of the eighth via V8 on the base substrate is within a range of an orthographic projection of the first opening 35 of the second plate 34 on the base substrate, the third insulating layer and the second insulating layer within the eighth via V8 are etched away to expose a surface of the first sub-plate, and the eighth via V8 is configured to enable a subsequently formed second connection electrode to be connected with the first plate 26 through the via.

In an exemplary implementation, an orthographic projection of the ninth via V9 on the base substrate is located within a range of an orthographic projection of an end (i.e., the first end portion) of the second plate 34 close to the first scan line 21 on the base substrate, the third insulating layer within the ninth via V9 is etched away to expose a surface of the second plate 34, and the ninth via V9 is configured to enable a subsequently formed first power supply line to be connected with the second plate 34 through the via to enable the second plate 34 of the storage capacitor to receive the first voltage signal.

In an exemplary implementation, an orthographic projection of the tenth via V10 on the base substrate is located within a range of an orthographic projection of an end (i.e., the second end) of the second plate 34 close to the light emitting control line 24 on the base substrate, the third insulating layer within the tenth via V10 is etched away to expose a surface of the second plate 34, and the tenth via V10 is configured to enable a subsequently formed first power supply line to be connected with the second plate 34 through the via to enable the second plate 34 of the storage capacitor to receive the first voltage signal.

In an exemplary implementation, an orthographic projection of the fourth hole group K4 on the base substrate is within a range of an orthographic projection of a first region of the fourth active layer on the base substrate, the fourth hole group K4 may include at least two eleventh vias V11, the third insulating layer, the second insulating layer, and the first insulating layer within the eleventh vias V11 are etched away to expose a surface of the first region of the fourth active layer, and the fourth hole group K4 is configured to enable a subsequently formed data line to be connected with the first region of the fourth active layer through the via group to enable a first electrode of the fourth transistor to receive a data signal.

In an exemplary implementation, the at least two eleventh vias V11 may be arranged in an array, for example, the fourth hole group K4 may include three eleventh vias V11 distributed in three rows and one column. In other implementations, the at least two eleventh vias V11 may be distributed in other ways or may be irregularly distributed, which is not limited in the present disclosure.

In an exemplary implementation, an orthographic projection of the fifth hole group K5 on the base substrate is located within a range of an orthographic projection of the first initial signal line 31 on the base substrate, the fifth hole group K5 may include at least two twelfth vias V12, the third insulating layer within the twelfth vias V12 is etched away to expose a surface of the first initial signal line 31, and the fifth hole group K5 is configured to enable a subsequently formed first connection electrode to be connected with the first initial signal line 31 through the via group. In an exemplary implementation, the orthographic projection of the fifth hole group K5 on the base substrate may be located within a range of an orthographic projection of the channel region of the first active layer on the base substrate.

In an exemplary implementation, the at least two twelfth vias V12 may be arranged in an array, for example, the fifth hole group K5 may include two twelfth vias V12 distributed in one row and two columns. In other implementations, the at least two twelfth vias V12 may be distributed in other ways or may be irregularly distributed, which is not limited in the present disclosure.

In an exemplary implementation, an orthographic projection of the thirteenth via V13 on the base substrate is within a range of an orthographic projection of the shielding electrode 33 on the base substrate, the fourth insulating layer within the thirteenth via V13 is etched away to expose a surface of the shielding electrode 33, and the thirteenth via V13 is configured to enable a subsequently formed first connection electrode to be connected with the shielding electrode 33 through the via to enable the shielding electrode 33 to receive a constant first initial signal.

In an exemplary implementation, an orthographic projection of fourteenth vias V14 of the sixth hole group K6 on the base substrate is within a range of an orthographic projection of the second initial signal line 32 on the base substrate, the sixth hole group K6 may include at least two fourteenth vias V14, the third insulating layer within the fourteenth vias V14 is etched away to expose a surface of the second initial signal line 32, and the sixth hole group K6 is configured to enable a subsequently formed sixth connection electrode to be connected with the second initial signal line 32 through the via group.

In an exemplary implementation, the at least two fourteenth vias V14 may be arranged in an array, for example, the sixth hole group K6 may include three fourteenth vias V14 distributed in one row and three columns. In other implementations, the at least two fourteenth vias V14 may be distributed in other ways or may be irregularly distributed, which is not limited in the present disclosure.

In an exemplary implementation, an orthographic projection of the fifteenth via V15 on the base substrate is located within a range of an orthographic projection of the first data transfer portion 25-1 on the base substrate, the third insulating layer and the second insulating layer within the fifteenth via V15 are etched away to expose a surface of the first data transfer portion 25-1, and the fifteenth via V15 is configured to enable a subsequently formed data line to be connected with the first data transfer portion 25-1 through the via.

In an exemplary implementation, an orthographic projection of the sixteenth via V16 on the base substrate is within a range of an orthographic projection of the first data transfer line 25 on the base substrate, the third insulating layer and the second insulating layer within the sixteenth via V16 are etched away to expose a surface of the first data transfer line 25, and the sixteenth via V16 is configured to enable a subsequently formed second data transfer line to be connected with the first data transfer line 25 through the via.

In an exemplary implementation, the at least one circuit unit may further include a seventh hole group K7, an orthographic projection of the seventh hole group K7 on the base substrate is within a range of an orthographic projection of the first initial signal line 31 on the base substrate, the seventh hole group K7 may include at least two seventeenth vias V17, the third insulating layer within the seventeenth vias V17 is etched away to expose a surface of the first initial signal line 31, and the seventh hole group K7 is configured to enable a subsequently formed first initial signal connection line to be connected with the first initial signal line 31 through the via group. In an exemplary implementation, the seventh hole group K7 may be located at a side of the first circuit unit away from the second circuit unit.

In an exemplary implementation, the at least two seventeenth vias V17 may be arranged in an array, for example, the seventh hole group K7 may include nine seventeenth vias V17 distributed in three rows and three columns. In other implementations, the at least two seventeenth vias V17 may be distributed in other ways or may be irregularly distributed, which is not limited in the present disclosure.

In an exemplary implementation, the at least one circuit unit may further include an eighth hole group K8, an orthographic projection of the eighth hole group K8 on the base substrate is within a range of an orthographic projection of the second initial signal line 32 on the base substrate, the eighth hole group K8 may include at least two eighteenth vias V18, the third insulating layer within the eighteenth vias V18 is etched away to expose a surface of the second initial signal line 32, and the eighth hole group K8 is configured to enable a subsequently formed second initial signal connection line to be connected with the second initial signal line 32 through the via group. In an exemplary implementation, the eighth hole group K8 may be located at a side of the third circuit unit away from the second circuit unit.

In an exemplary implementation, the at least two eighteenth vias V18 may be arranged in an array, for example, the eighth hole group K8 may include nine eighteenth vias V18 distributed in three rows and three columns. In other implementations, the at least two eighteenth vias V18 may be distributed in other ways or may be irregularly distributed, which is not limited in the present disclosure.

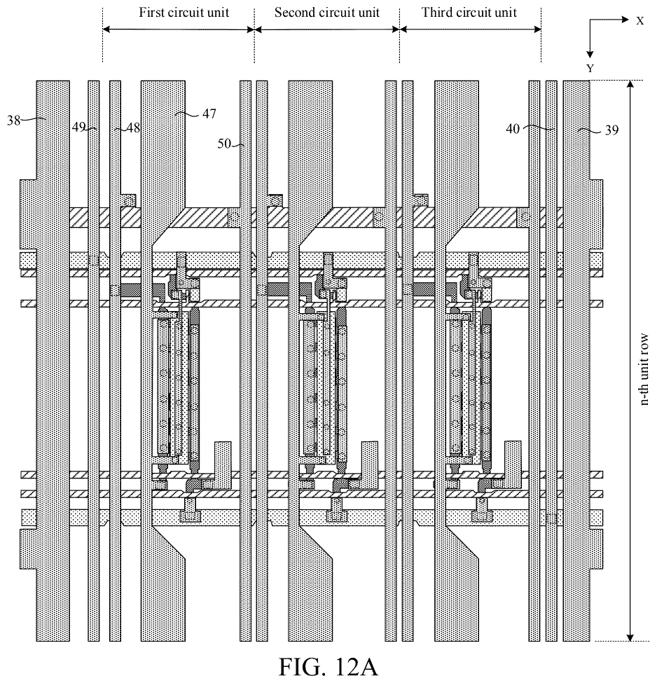

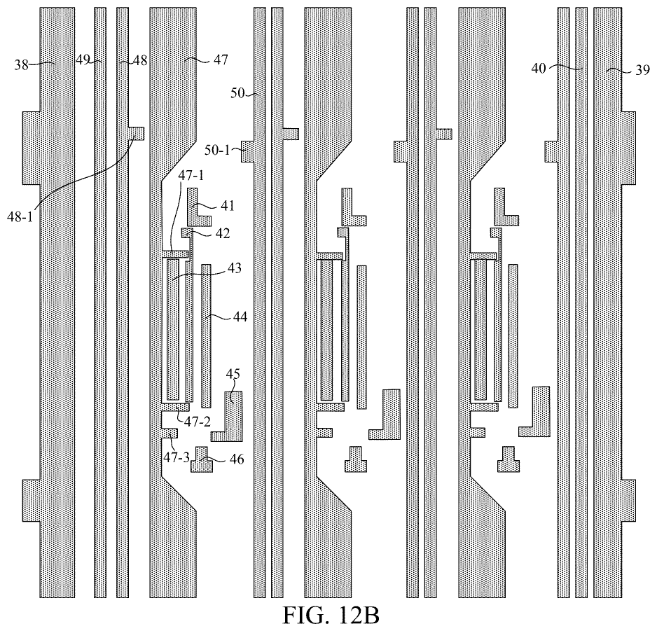

(5) A pattern of a third conductive layer is formed. In an exemplary implementation, forming the third conductive layer may include: depositing a third conductive thin film on the base substrate on which the aforementioned pattern is formed, patterning the third conductive thin film by a patterning process to form a third conductive layer disposed on the third insulating layer, as shown in FIGS. 12A and 12B, FIG. 12A is a schematic diagram of the display substrate after a third conductive layer is formed in FIG. 7, and FIG. 12B is a schematic diagram of the third conductive layer in FIG. 12A. In an exemplary implementation, the third conductive layer may be referred to as a first source-drain metal (SD1) layer.

In an exemplary implementation, the patterns of the third conductive layers of the plurality of circuit units in the display substrate may each include a first connection electrode 41, a second connection electrode 42, a third connection electrode 43, a fourth connection electrode 44, a fifth connection electrode 45, a sixth connection electrode 46, a first power supply line 47, a data line 48, and a second data transfer line 50.

In an exemplary implementation, the first power supply line 47 may be in a shape of a line in which a main body portion extends along the second direction Y. The first power supply line 47 may be located at a side of the second plate 34 in an opposite direction of the first direction X.

In an exemplary implementation, a first power supply connection block 47-1 may be provided on a side of the first power supply line 47 close to the second plate 34, a first end of the first power supply connection block 47-1 is connected to the first power supply line 47, a second end of the first power supply connection block 47-1 extends to a side close to the second plate 34, and the first power supply line 47 and the first power supply connection block 47-1 may be of an interconnected integral structure. The second end of the first power supply connection block 47-1 may be connected to a first end portion of the second plate 34 through the ninth via V9, thereby realizing the connection between the second plate 34 and the first power supply line 47.

In an exemplary implementation, a second power supply connection block 47-2 may be provided on a side of the first power supply line 47 close to the second plate 34, a first end of the second power supply connection block 47-2 is connected to the first power supply line 47, a second end of the second power supply connection block 47-2 extends to a side close to the second plate 34, and the first power supply line 47 and the second power supply connection block 47-2 may be of an interconnected integral structure. The second end of the second power supply connection block 47-2 may be connected to a second end portion of the second plate 34 through the tenth via V10, thereby realizing the connection between the second plate 34 and the first power supply line 47. Since the ninth via V9 and the tenth via V10 are respectively located at two sides of the second plate 34 in the second direction Y, by providing the first power supply connection block 47-1 and the second power supply connection block 47-2 on the first power supply line 47, the first power supply line 47 is connected to the second plate 34 through the ninth via V9 using the first power connection block 47-1, and the first power supply line 47 is connected to the second plate 34 through the tenth via V10 using the second power connection block 47-2, so that the second plate 34 can receive the first voltage signal at two end portions in the second direction Y simultaneously, which in turn makes the first voltage signal received by the storage capacitor more stable, and contributes to the stable operation of the pixel circuit.

In an exemplary implementation, a third power supply connection block 47-3 may be provided on a side of the first power supply line 47 close to the second plate 34, a first end of the third power supply connection block 47-3 is connected to the first power supply line 47, a second end of the third power supply connection block 47-3 extends to a side close to the second plate 34, and the first power supply line 47 and the third power supply connection block 47-3 may be of an interconnected integral structure. The second end of the third power supply connection block 47-3 may be connected to a first region of the fifth active layer through the fifth via V5 of the second hole group K2, so that a first electrode of the fifth transistor T5 can receive the first voltage signal.

In an exemplary implementation, the first power supply line 47 may be of a non-equal width design, and the width of the first power supply line 47 at a portion passing through the pixel drive circuit may be smaller than the width of other portions, and the first power supply line 47 of a non-equal width design not only facilitates the layout of the pixel structure, but also reduces the parasitic capacitance between the first power supply line and the data line.

In an exemplary implementation, the data line 48 may be in a shape of a line in which a main body portion extends along the second direction Y, the data line 48 may be located at a side of the first power supply line 47 in an opposite direction of the first direction X, and the data lines 48 between adjacent circuit units are not adjacent. An orthographic projection of the data line 48 on the base substrate may overlap an orthographic projection of the first notch 31-1 provided on the first initial signal line 31 on the base substrate, and an orthographic projection of the data line 48 on the base substrate may overlap an orthographic projection of the second notch 32-1 provided on the second initial signal line 32 on the base substrate. This arrangement reduces the overlapping area between the data line 48 and the first initial signal line 31 and the second initial signal line 32, and helps to reduce the coupling capacitance.

In an exemplary implementation, the data line 48 may be connected to a first region of the fourth active layer through the eleventh via V11 of the fourth hole group K4, so that a first electrode of the fourth transistor T4 can receive a data signal.

In an exemplary implementation, a data connection block 48-1 may be provided on a side of the data line 48 close to the first power supply line 47, a first end of the data connection block 48-1 is connected to the data line 48, a second end of the data connection block 48-1 extends to a side close to the second plate 34, and the data line 48 and the data connection block 48-1 may be of an interconnected integral structure. The second end of the data connection block 48-1 may be connected to the first data transfer portion 25-1 through the fifteenth via V15, thereby realizing the connection between the data line 48 and the first data transfer line 25.

In an exemplary implementation, the second data transfer line 50 may be in a shape of a line in which a main body portion extends along the second direction Y, and the second data transfer line 50 may be located at a side of the second plate 34 in the first direction X. By using the first power supply line 47 and the second data transfer line 50 to make the data lines 48 of adjacent circuit units not adjacent to each other, it helps to reduce signal crosstalk between the data lines of different circuit units and improve the display quality.

In an exemplary implementation, a second data transfer portion 50-1 may be provided on a side of the second data transfer line 50 close to the second plate 34, a first end of the second data transfer portion 50-1 is connected to the second data transfer line 50, a second end of the second data transfer portion 50-1, after extending to a side away from the second plate 34, is connected to the first data transfer line 25 through the sixteenth via V16, and the second data transfer line 50 and the second data transfer portion 50-1 may be of an interconnected integral structure. Since the data line 48 can be connected to the second data transfer line 50 through the first data transfer line 25, the second data transfer line 50 can extend from the display region to the lower bezel along the second direction Y, and can be connected to the integrated circuit of the bonding region of the lower bezel to form a data fan-out line located in the display region (Fanout in AA, FIAA for short) structure. By adopting the FIAA structure, the width of the arrangement of a plurality of fan-out traces of the lower bezel in the first direction X can be reduced, so that the size of the lower bezel can be effectively reduced, which is beneficial to realize a display substrate with a narrow bezel.

In an exemplary implementation, the first connection electrode 41 may be in an “L” shape, and may be located between the first power supply line 47 and the second data transfer line 50, and the first connection electrode 41 may be connected to a first region of the first active layer through the first via V1 and connected to the first initial signal line 31 through the twelfth via V12, so that the first electrode of the first transistor receives the first initial signal. The first connection electrode 41 may also be connected to the shielding electrode 33 through the thirteenth via V13, so that the shielding electrode 33 receives a constant first initial signal, thereby avoiding other signals (such as data voltage jumps) from affecting the potential of the second transistor, and improving the display effect.

In an exemplary implementation, the second connection electrode 42 may be in a shape of a strip extending along the second direction Y, may be located between the first power supply line 47 and the second data transfer line 50, the second connection electrode 42 may be connected to a second region of the first active layer (also a second region of the second active layer) through the second via V2 of the first hole group K1, and may also be connected to a plurality of first sub-plates 26-1 through a plurality of eighth vias V8, thereby realizing the connection between the second connection electrode 42 and the first plate 26. The second connection electrode 42 may serve as the first node N1 in the pixel circuit. The third transistor serves as a drive transistor in the pixel circuit, and by providing a plurality of (for example, six) drive transistors in the pixel drive circuit, and first electrodes, gate electrodes, and second electrodes of the plurality of drive transistors are connected to each other respectively, it is advantageous to increase the drive current provided by the pixel drive circuit, thereby improving the display quality of the display substrate.

In an exemplary implementation, the third connection electrode 43 may be in a shape of a strip extending along the second direction Y, may be located between the first power supply line 47 and the second connection electrode 42, and the third connection electrode 43 may be connected to a first region of the third active layer (also a second region of the fourth active layer and a second region of the fifth active layer) through the third via V3. The third connection electrode 43 may serve as the second node N2 in the pixel circuit.

In an exemplary implementation, the fourth connection electrode 44 may be in a shape of a strip extending along the second direction Y, may be located between the second connection electrode 42 and the second data transfer line 50, and the fourth connection electrode 44 may be connected to a second region of the third active layer (also a first region of the second active layer and a first region of the sixth active layer) through the fourth via V4. The fourth connection electrode 44 may serve as the third node N3 in the pixel circuit.

In an exemplary implementation, the fifth connection electrode 45 may be in a “J” shape, may be located between the fourth connection electrode 44 and the second data transfer line 50, and the fifth connection electrode 45 may be connected to a second region of the sixth active layer (also a second region of the seventh active layer) through the sixth via V6 of the third hole group K3. The fifth connection electrode 45 may serve as the second electrode of the sixth transistor T6 and the second electrode of the seventh transistor T7 and be configured to be connected to a subsequently formed anode connection electrode.

In an exemplary implementation, the sixth connection electrode 46 may be in an inverted “T” shape, may be located between the first power supply line 47 and the fifth connection electrode 45, the sixth connection electrode 46 may be connected to a first region of the seventh active layer through the seventh via V7, and may be connected to the second initial signal line 32 through the fourteenth via V14 of the sixth hole group K6, so that a first electrode of the seventh transistor receives the second initial signal.

In an exemplary implementation, the pattern of the third conductive layer of at least one circuit unit in the display substrate may further include a first initial signal connection line 49. The first initial signal connection line 49 may be in a shape of a line in which a main body portion extends along the second direction Y. The first initial signal connection line 49 may be located at a side of the first circuit unit away from the second circuit unit, and the first initial signal connection line 49 may be connected to the first initial signal line 31 through the seventeenth via V17 of the seventh hole group K7. The first initial signal connection line 49 and the first initial signal line 31 may constitute a net-like connecting structure for transmitting the first initial signal, thereby reducing the voltage drop of the first initial signal, which is beneficial to improving the uniformity of the transmission of the first initial signal, avoiding poor display of the display substrate, and ensuring the display effect of the display substrate.

In an exemplary implementation, one first initial signal connection line 49 may be provided every three circuit units along the first direction X, and more or less first initial signal connection lines 49 may be provided as necessary, which is not limited in the present disclosure.

In an exemplary implementation, the pattern of the third conductive layer of at least one circuit unit in the display substrate may further include a second initial signal connection line 40. The second initial signal connection line 40 may be in a shape of a line in which a main body portion extends along the second direction Y. The second initial signal connection line 40 may be located at a side of the third circuit unit away from the second circuit unit, and the second initial signal connection line 40 may be connected to the second initial signal line 32 through the eighteenth via V18 of the eighth hole group K8. The second initial signal connection line 40 and the second initial signal line 32 may constitute a net-like connecting structure for transmitting the second initial signal, thereby reducing the voltage drop of the transmission of the second initial signal, which is beneficial to improving the uniformity of the transmission of the second initial signal, avoiding poor display of the display substrate, and ensuring the display effect of the display substrate.

In an exemplary implementation, one second initial signal connection line 40 may be provided every three circuit units along the first direction X, and more or less second initial signal connection lines 40 may be provided as necessary, which is not limited in the present disclosure.

In an exemplary implementation, the plurality of circuit units of the display substrate may be divided into a plurality of circuit unit groups, and for example, each circuit unit group may include three circuit units sequentially arranged along the first direction X. The first circuit unit, the second circuit unit, and the third circuit unit in the present example may be used as one circuit unit group. The pattern of the third conductive layer of at least one circuit unit group may include a first auxiliary connection line 38. The first auxiliary connection line 38 may be in a shape of a line in which a main body portion extends along the second direction Y. The first auxiliary connection line 38 may be located at a side of the first initial signal connection line 49 away from the first circuit unit. The first auxiliary connection line 38 is provided to be connected to a subsequently formed first connection ring and can be used for transmitting the first voltage signal.

In an exemplary implementation, the pattern of the third conductive layer of at least one circuit unit group in the display substrate may further include a second auxiliary connection line 39. The second auxiliary connection line 39 may be in a shape of a line in which a main body portion extends along the second direction Y. The second auxiliary connection line 39 may be located at a side of the second initial signal connection line 40 away from the third circuit unit. The second auxiliary connection line 39 is provided to be connected to a subsequently formed first connection ring and can be used for transmitting the first voltage signal.

In this example, the transmission of the first voltage signal along the second direction Y can be realized by providing a plurality of first power supply lines 47, first auxiliary connection lines 38, and second auxiliary connection lines 39. By providing the first auxiliary connection lines 38 and the second auxiliary connection line 39s, it may be advantageous to shield the influence between adjacent circuit unit groups.

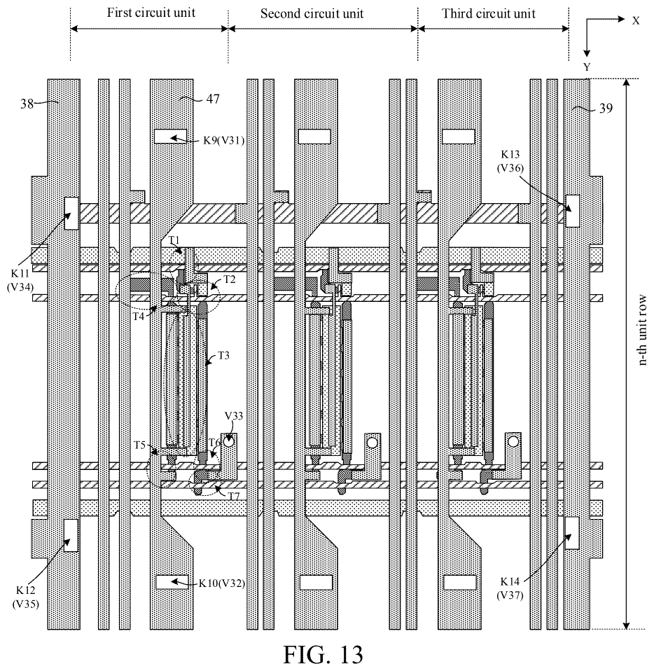

(6) A pattern of a fourth insulation layer is formed. In an exemplary implementation, forming the pattern of the fourth insulating layer may include: depositing a fourth insulating thin film on the base substrate on which the aforementioned pattern is formed, patterning the fourth insulating thin film by a patterning process to form a fourth insulating layer, coating a fifth insulating thin film on the fourth insulating layer, patterning the fifth insulating thin film by a patterning process to form a fifth insulating layer, and the fifth insulating layer in each circuit unit may be provided with a plurality of vias, as shown in FIG. 13. FIG. 13 is a schematic view of a display substrate after a fifth insulation layer is formed in FIG. 7.

In an exemplary implementation, the plurality of vias of each circuit unit in the display substrate includes at least a ninth hole group K9, a tenth hole group K10, and a thirty-third via V33. Orthographic projections of the ninth hole group K9 and the tenth hole group K10 on the base substrate may be within a range of an orthographic projection of the first power supply line 47 on the base substrate.

In an exemplary implementation, an orthographic projection of the ninth hole group K9 on the base substrate may be located at a side of the first connection electrode 41 in an opposite direction of the second direction Y, the ninth hole group K9 may include at least two thirty-first vias V31, the fourth insulating layer and the fifth insulating layer within the thirty-first vias V31 are removed to expose a surface of the first power supply line 47, and the ninth hole group K9 is configured to enable a subsequently formed first connection ring to be connected with the first power supply line 47 through the via group. The quantity and manner of distribution of the thirty-first vias V31 in the ninth hole group K9 can be described with reference to the foregoing hole groups, which will not be repeated here.

In an exemplary implementation, an orthographic projection of the tenth hole group K10 on the base substrate may be located at a side of the sixth connection electrode 46 in the second direction Y, the tenth hole group K10 may include at least two thirty-second vias V32, the fourth insulating layer and the fifth insulating layer within the thirty-second vias V32 are removed to expose a surface of the first power supply line 47, and the tenth hole group K10 is configured to enable a subsequently formed first connection ring to be connected with the first power supply line 47 through the via group.

In an exemplary implementation, an orthographic projection of the thirty-third via V33 on the base substrate may be located within a range of an orthographic projection of the fifth connection electrode 45 on the base substrate, the fourth insulating layer and the fifth insulating layer within the thirty-third via V33 are removed to expose a surface of the fifth connection electrode 45, and the thirty-third via V33 is configured to enable the first anode connection electrode, the second anode connection electrode, and the third anode connection electrode which are formed subsequently to be connected with the corresponding fifth connection electrode 45 through the via, respectively.

In an exemplary implementation, the fifth insulating layer of at least one circuit unit group may be provided with an eleventh hole group K11 and a twelfth hole group K12, orthographic projections of the eleventh hole group K11 and the twelfth hole group K12 on the base substrate may be within a range of the orthographic projection of the first auxiliary connection line 38 on the base substrate, the eleventh hole group K11 includes at least two thirty-fourth vias V34, the twelfth hole group K12 includes at least two thirty-fifth vias V35, the fourth insulating layer and the fifth insulating layer within the thirty-fourth vias V34 and the thirty-fifth vias V35 are removed to expose a surface of the first auxiliary connection line 38, and the eleventh hole group K11 and the twelfth hole group K12 are configured to enable a subsequently formed first connection ring to be connected with the first auxiliary connection line 38 through the via group. The twelfth hole group K12 may be located at a side of the eleventh hole group K11 in the second direction Y.

In an exemplary implementation, the fifth insulating layer of at least one circuit unit group may be provided with a thirteenth hole group K13 and a fourteenth hole group K14, orthographic projections of the thirteenth hole group K13 and the fourteenth hole group K14 on the base substrate may be located within a range of an orthographic projection of the second auxiliary connection line 39 on the base substrate, the thirteenth hole group K13 may include at least two thirty-sixth vias V36, and the fourteenth hole group K14 may include at least two thirty-seventh vias V37, the fourth insulating layer and the fifth insulating layer within the thirty-sixth vias V36 and the thirty-seventh vias V37 are removed, to expose a surface of the second auxiliary connection line 39, and the thirteenth hole group K13 and the fourteenth hole group K14 are configured to enable a subsequently formed first connection ring to be connected with the second auxiliary connection line 39 through the via group. The fourteenth hole group K14 may be located at a side of the thirteenth hole group K13 in the second direction Y.

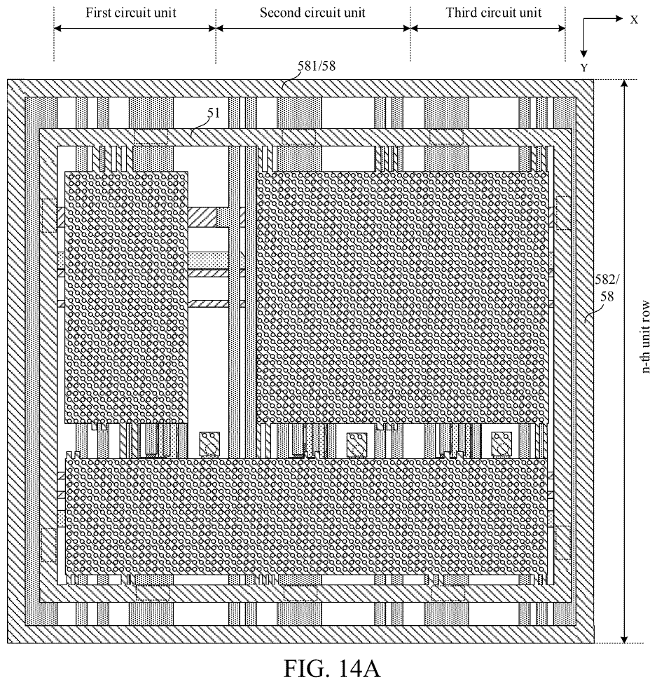

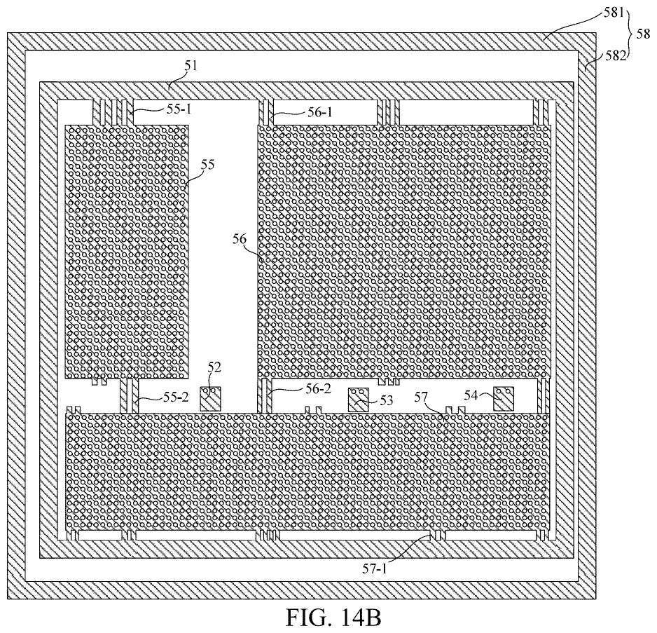

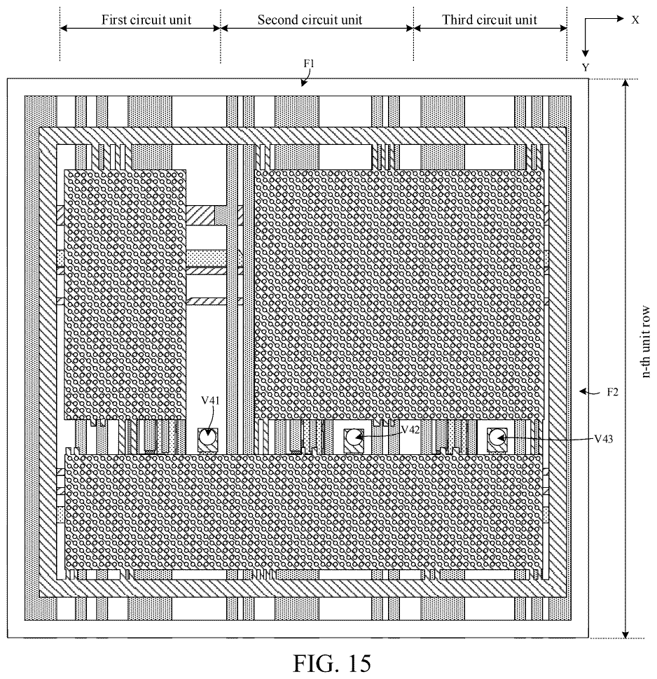

(7) A pattern of a fourth conductive layer is formed. In an exemplary implementation, forming the pattern of the fourth conductive layer may include: depositing a fourth conductive thin film on the base substrate on which the aforementioned pattern is formed, patterning the fourth conductive thin film by a patterning process to form a fourth conductive layer disposed on the fifth insulating layer, as shown in FIGS. 14A and 14B, FIG. 14A is a schematic diagram of a display substrate after a fourth conductive layer is formed in FIG. 7, and FIG. 14B is a schematic diagram of a fourth conductive layer in FIG. 14A. In an exemplary implementation, the fourth conductive layer may be referred to as a second source-drain metal (SD2) layer.

In an exemplary implementation, the patterns of the fourth conductive layers of the plurality of circuit units in the display substrate may each include a first connection ring 51, a first anode connection electrode 52, a second anode connection electrode 53, a third anode connection electrode 54, a first anode pad 55, a second anode pad 56, a third anode pad 57, and a first transmission ring 58.

In an exemplary implementation, the first connection ring 51 may be in a shape of a ring, such as a rectangular ring. An orthographic projection of the first connection ring 51 on the base substrate may surround the periphery of the three pixel drive circuits. The first connection ring 51 can be connected to the first power supply lines 47 in the plurality of circuit units through the ninth hole group K9 and the tenth hole group K10 located within the first circuit unit, the second circuit unit and the third circuit unit, so that the first power supply lines 47 in the plurality of circuit units communicate with each other, which helps to reduce the voltage drop of the first voltage signal, enable different circuit units to receive a stable first voltage signal, and improve the uniformity of the transmission of the first voltage signal.

In an exemplary implementation, an orthographic projection of the first connection ring 51 on the base substrate may be at least partially overlapped with an orthographic projection of the first auxiliary connection line 38 on the base substrate, and the first connection ring 51 may be connected to the first auxiliary connection line 38 through the eleventh hole group K11 and the twelfth hole group K12, so that the first auxiliary connection line 38 transmits the first voltage signal, which helps to reduce the voltage drop of the first voltage signal. The orthographic projection of the first connection ring 51 on the base substrate may be at least partially overlapped with an orthographic projection of the second auxiliary connection line 39 on the base substrate, and the first connection ring 51 may be connected to the second auxiliary connection line 39 through the thirteenth hole group K13 and the fourteenth hole group K14, so that the second auxiliary connection line 39 transmits the first voltage signal, which helps to reduce the voltage drop of the first voltage signal.

In an exemplary implementation, the first anode pad 55, the second anode pad 56, and the third anode pad 57 may be located on an inside of the first connection ring 51. The first anode pad 55, the second anode pad 56, and the third anode pad 57 may in a shape of a rectangle, corners of the rectangle may be provided with chamfers. The first anode pad 55 and the second anode pad 56 may be located on a side of the third anode pad 57 in an opposite direction of the second direction Y, and the first anode pad 55 may be located on a side of the second anode pad 56 in an opposite direction of the first direction X. By forming the first anode pad 55, the second anode pad 56, and the third anode pad 57, it is helpful to ensure the flatness of the subsequently formed anode.

In an exemplary implementation, a side of the first anode pad 55 away from the third anode pad 57 may be provided with a first pad protrusion 55-1, a first end of the first pad protrusion 55-1 may be connected to the first anode pad 55, and a second end of the first pad protrusion 55-1 may be connected to the first connection ring 51 after extending in an opposite direction of the second direction Y. A side of the first anode pad 55 close to the third anode pad 57 may be provided with a second pad protrusion 55-2, a first end of the second pad protrusion 55-2 may be connected to the first anode pad 55, and a second end of the second pad protrusion 55-2 may be connected to the first connection ring 51 after extending toward the second direction Y. The first anode pad 55, the first pad protrusion 55-1, and the second pad protrusion 55-2 may be of an interconnected integral structure.

In an exemplary implementation, a side of the second anode pad 56 away from the third anode pad 57 may be provided with a third pad protrusion 56-1, a first end of the third pad protrusion 56-1 may be connected to the second anode pad 56, and a second end of the third pad protrusion 56-1 may be connected to the first connection ring 51 after extending in an opposite direction of the second direction Y. A side of the second anode pad 56 close to the third anode pad 57 may be provided with a fourth pad protrusion 56-2, a first end of the fourth pad protrusion 56-2 may be connected to the second anode pad 56, and a second end of the fourth pad protrusion 56-2 may be connected to the third anode pad 57 after extending toward the second direction Y. The second anode pad 56, the third pad protrusion 56-1, and the fourth pad protrusion 56-2 may be of an interconnected integral structure.

In an exemplary implementation, a side of the third anode pad 57 away from the first anode pad 55 and the second anode pad 56 may be provided with a fifth pad protrusion 57-1, a first end of the fifth pad protrusion 57-1 may be connected to the third anode pad 57, and a second end of the fifth pad protrusion 57-1, after extending along the second direction Y, may be connected to the first connection ring 51. The third anode pad 57 and the fifth pad protrusion 57-1 may be of an interconnected integral structure.

In some examples, the first anode pad 55, the second anode pad 56, the third anode pad 57, the first connection ring 51, and a plurality of pad protrusions may be of an interconnected integral structure. Orthographic projections of the first anode pad and the second anode pad on the base substrate may cover orthographic projections of the first connection electrode 41, the second connection electrode 42, the third connection electrode 43, and the fourth connection electrode 44 on the base substrate, which may be beneficial to shield interference to the pixel drive circuit.

In some examples, the first anode pad 55, the second anode pad 56, and the third anode pad 57 may include a plurality of through holes which expose a surface of the fifth insulating layer, and may be arranged in an array. In this example, by providing through holes in the anode pads, it is beneficial for an organic film layer to permeate air. The present embodiment is not limited to the arrangement of the plurality of through holes.

In an exemplary implementation, the first anode connection electrode 52, the second anode connection electrode 53, and the third anode connection electrode 54 may in a shape of a rectangle, corners of the rectangle may be provided with chamfers. Orthographic projections of the first anode connection electrode 52, the second anode connection electrode 53, and the third anode connection electrode 54 on the base substrate may be at least partially overlapped with an orthographic projection of the fifth connection electrode 45 within the circuit unit in which they are located on the base substrate. The first anode connection electrode 52, the second anode connection electrode 53 and the third anode connection electrode 54 can be connected to the fifth connection electrode 45 in the circuit unit in which they are located through the thirty-third via V33, the first anode connection electrode 52 can be connected to the first anode formed subsequently, the second anode connection electrode 53 can be connected to the second anode formed subsequently, and the third anode connection electrode 54 can be connected to the third anode formed subsequently, so that a corresponding anode is connected to a second electrode of the sixth transistor T6 (a second electrode of the seventh transistor T7) of the pixel drive circuit.

In some examples, the first anode connection electrode 52, the second anode connection electrode 53, and the third anode connection electrode 54 may include a plurality of through holes exposing a surface of the fifth insulating layer, and the plurality of through holes may be arranged in an array or other form of distribution to facilitate air permeation of an organic film layer.

In an exemplary implementation, the first transmission ring 58 may be in a shape of a ring, such as a rectangular ring. The first transmission ring 58 may be located at the periphery of the first connection ring 51. The first transmission ring 58 may be formed by connecting two first transmission line segments 581 extending in the first direction X and two second transmission line segments 582 extending the second direction Y head to tail. The first transmission line segment 581 may be part of the first transmission line 591, and the second transmission line segment 582 may be part of the second transmission line 592. The first transmission ring 58 may be configured to transmit the second voltage signal.

(8) A pattern of a sixth insulation layer is formed. In an exemplary implementation, forming a pattern of a sixth insulating layer may include coating a sixth insulating thin film on the base substrate on which the aforementioned pattern is formed, patterning the sixth insulating thin film by a patterning process to form a sixth insulating layer, and the sixth insulating layer in each circuit unit may be provided with a plurality of vias, as shown in FIG. 15. FIG. 15 is a schematic view of a display substrate after a sixth insulation layer is formed in FIG. 7.

In an exemplary implementation, the plurality of vias of each circuit unit group in the display substrate includes at least a forty-first via V41, a forty-second via V42, and a forty-third via V43.

In an exemplary implementation, an orthographic projection of the forty-first via V41 on the base substrate is within a range of an orthographic projection of the first anode connection electrode 52 on the base substrate, the sixth insulating layer within the forty-first via V41 is removed to expose a surface of the first anode connection electrode 52, and the forty-first via V41 is configured to enable a subsequently formed first anode to be connected with the first anode connection electrode 52 through the via.

In an exemplary implementation, an orthographic projection of the forty-second via V42 on the base substrate is within a range of an orthographic projection of the second anode connection electrode 53 on the base substrate, the sixth insulating layer within the forty-second via V42 is removed to expose a surface of the second anode connection electrode 53, and the forty-second via V42 is configured to enable a subsequently formed second anode to be connected with the second anode connection electrode 53 through the via.

In an exemplary implementation, an orthographic projection of the forty-third via V43 on the base substrate is within a range of an orthographic projection of the third anode connection electrode 54 on the base substrate, the sixth insulating layer within the forty-third via V43 is removed to expose a surface of the third anode connection electrode 54, and the forty-third via V43 is configured to enable a subsequently formed third anode to be connected with the third anode connection electrode 54 through the via.

In an exemplary implementation, the at least one circuit unit group may further include a first through-hole strip F1 extending along the first direction X and a second through-hole strip F2 extending along the second direction Y. Orthographic projections of the first through-hole strip F1 and the second through-hole strip F2 on the base substrate may be within a range of an orthographic projection of the first transmission ring 58 on the base substrate, the sixth insulating layer within the first through-hole strip F1 and the second through-hole strip F2 may be removed to expose at least a portion of a surface of the first transmission ring 58, and the first through-hole strip F1 and the second through-hole strip F2 may be configured to enable a subsequently formed second transmission ring to be connected with the first transmission ring 58 through the two through-hole strips. In some examples, the first through-hole strip F1 and the second through-hole strip F2 may communicate with each other. However, the present embodiment is not limited thereto. For example, the first through-hole strip F1 and the second through-hole strip F2 may not communicate with each other.

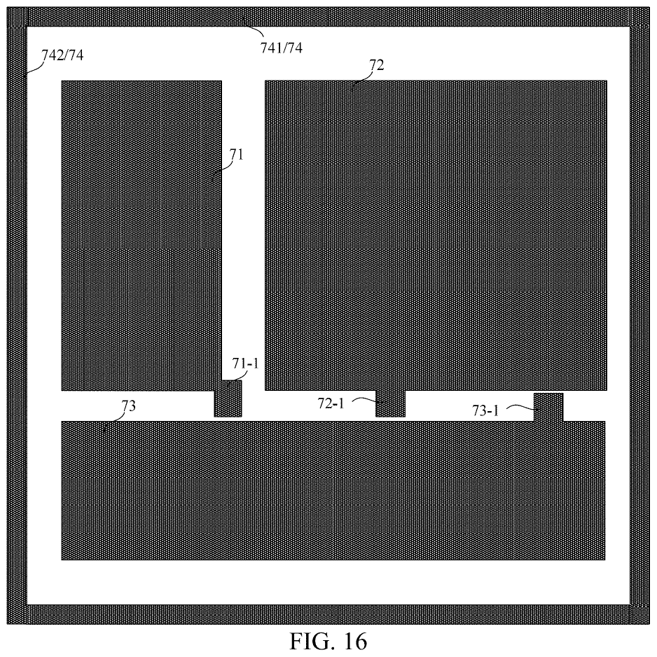

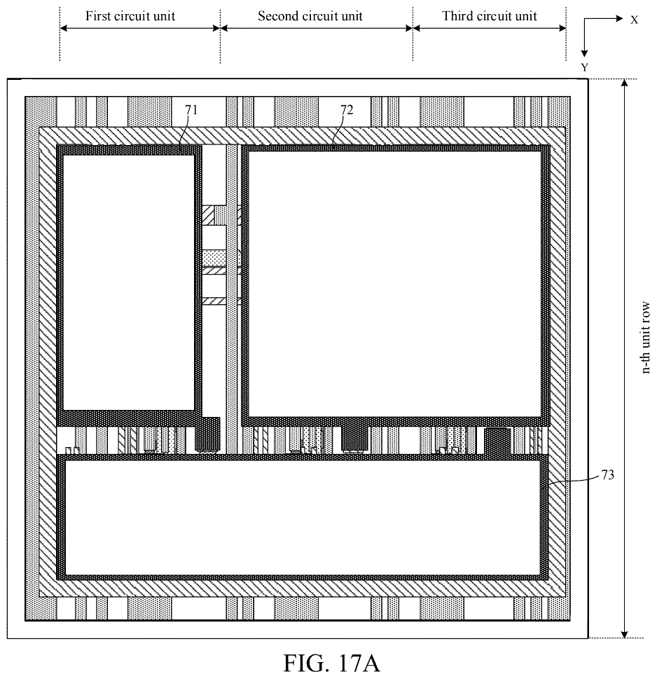

(9) A pattern of an anode layer is formed. In an exemplary implementation, forming the pattern of the anode layer may include: depositing an anode thin film on the base substrate on which the aforementioned pattern is formed, patterning the anode thin film by a patterning process to form an anode layer disposed on the sixth insulating layer, as shown in FIG. 16, and FIG. 16 is a schematic diagram of the anode layer in FIG. 7.

In an exemplary implementation, the patterns of the anode layers of the plurality of circuit unit groups in the display substrate may include a first anode 71, a second anode 72, and a third anode 73. The first anode 71, the second anode 72, and the third anode 73 may in a shape of a rectangle, corners of the rectangle may be provided with chamfers.

In an exemplary implementation, a first anode connection block 71-1 may be provided on a side of the first anode 71 close to the third anode 73, a first end of the first anode connection block 71-1 may be connected to the first anode 71, and a second end of the first anode connection block 71-1, after extending along the second direction Y, may be connected to the first anode connection electrode 52 through the forty-first via V41 in the first circuit unit. The first anode 71 and the first anode connection block 71-1 may be of an interconnected integral structure.

In an exemplary implementation, a second anode connection block 72-1 may be provided on a side of the second anode 72 close to the third anode 73, a first end of the second anode connection block 72-1 may be connected to the second anode 72, and a second end of the second anode connection block 72-1, after extending along the second direction Y, may be connected to the second anode connection electrode 53 through the forty-second via V42 in the second circuit unit. The second anode 72 and the second anode connection block 72-1 may be of an interconnected integral structure.

In an exemplary implementation, a third anode connection block 73-1 may be provided on a side of the third anode 73 close to the second anode 72, a first end of the third anode connection block 73-1 may be connected to the third anode 73, and a second end of the third anode connection block 73-1, after extending in an opposite direction of the second direction Y, may be connected to the third anode connection electrode 54 through the forty-third via V43 in the third circuit unit. The third anode 73 and the third anode connection block 73-1 may be of an interconnected integral structure.

In an exemplary implementation, the anode layer of the at least one circuit unit group may further include a second transmission ring 74. The second transmission ring 74 may be formed by connecting two adjacent third transmission lines 741 extending along the first direction X and two adjacent fourth transmission lines 742 extending along the second direction Y. The second transmission ring 74 may be connected to the first transmission ring 58 through the first through-hole strip F1 and the second through-hole strip F2. The first transmission ring 58 may be connected to a subsequently formed cathode layer through the second transmission ring 74, thereby facilitating the assurance of the uniformity of the transmission of the second voltage signal.

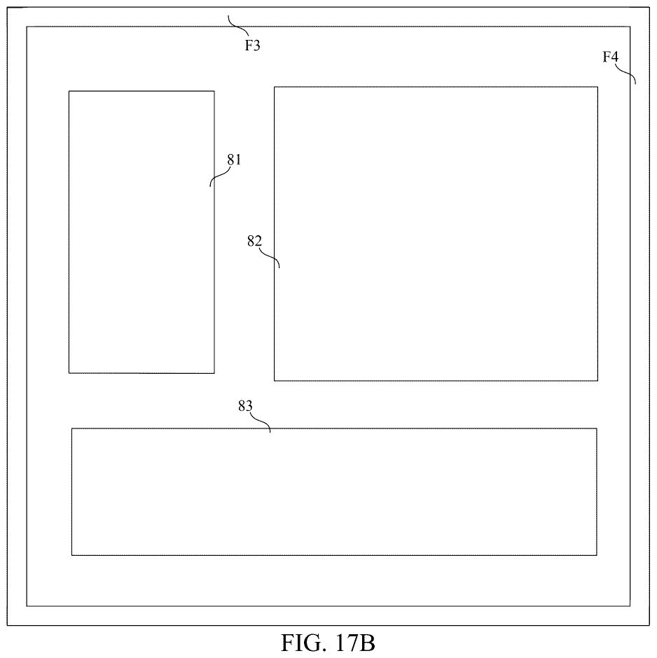

(10) A pattern of a pixel definition layer is formed. In an exemplary implementation, forming a pattern of a pixel definition layer may include: coating a pixel definition thin film on the base substrate on which the aforementioned pattern is formed, patterning the pixel definition thin film by a patterning process to form a pixel definition layer disposed on the anode layer, as shown in FIGS. 17A and 17B, FIG. 17A is a schematic diagram of a display substrate after a pixel definition layer is formed on the structure shown in FIG. 7, and FIG. 17B is a schematic diagram of the pixel definition layer in FIG. 17A.

In an exemplary implementation, the pattern of the pixel definition layer of one circuit unit group of the display substrate may be provided with a plurality of openings, including, for example, a first anode opening 81, a second anode opening 82, and a third anode opening 83.

In an exemplary implementation, an orthographic projection of the first anode opening 81 on the base substrate may be located within a range of an orthographic projection of the first anode 71 on the base substrate, and the pixel definition layer within the first anode opening 81 is removed to expose at least a portion of a surface of the first anode 71, so that a subsequently formed light emitting layer can be connected to the first anode 71.

In an exemplary implementation, an orthographic projection of the second anode opening 82 on the base substrate may be within a range of an orthographic projection of the second anode 72 on the base substrate, and the pixel definition layer within the second anode opening 82 is removed to expose at least a portion of a surface of the second anode 72 so that a subsequently formed light emitting layer can be connected to the second anode 72.

In an exemplary implementation, an orthographic projection of the third anode opening 83 on the base substrate may be located within a range of an orthographic projection of the third anode 73 on the base substrate, and the pixel definition layer within the third anode opening 83 is removed to expose at least a portion of a surface of the third anode 73 so that a subsequently formed light emitting layer can be connected to the third anode 73.

In an exemplary implementation, the pixel definition layer of at least one circuit unit group may further be provided with a third through-hole strip F3 extending along the first direction X and a fourth through-hole strip F4 extending along the second direction Y. Orthographic projections of the third through-hole strip F3 and the fourth through-hole strip F4 on the base substrate may be located within a range of an orthographic projection of the second transmission ring 74 on the base substrate, and the pixel definition layers within the third through-hole strip F3 and the fourth through-hole strip F4 may be removed to expose at least a portion of a surface of the second transmission ring 74 so that a subsequently formed cathode layer may be connected to the second transmission ring 74. In some examples, the third through-hole strip F3 and the fourth through-hole strip F4 may communicate with each other. However, the present embodiment is not limited thereto. For example, the third through-hole strip F3 and the fourth through-hole strip F4 may not communicate with each other.

In an exemplary implementation, a subsequent preparation process may include forming a pattern of a light emitting layer, a pattern of a cathode layer, an encapsulation layer, and the like, which will not be repeated here.

So far, preparation of the display substrate of the present embodiment on the base substrate is completed. In a plane parallel to the display substrate, the circuit structure layer may include a plurality of circuit units, each circuit unit may include a pixel drive circuit, and a first scan line, a second scan line, a third scan line, a light emitting control line, a first initial signal line, a second initial signal line, a first power supply line, a second power supply line, and a data line connected to the pixel drive circuit. In a plane perpendicular to the display substrate, the display substrate may include at least a semiconductor layer, a first insulating layer, a first conductive layer, a second insulating layer, a second conductive layer, a third insulating layer, a third conductive layer, a fourth insulating layer, a fourth conductive layer, a fifth insulating layer, an anode layer, and a pixel definition layer which are stacked sequentially on the base substrate. Active layers of the first transistor T1 to the seventh transistor T7 may be provided in the semiconductor layer, the first scan line 21, the second scan line 22, the third scan line 23, the light emitting control line 24, the first data transfer line 25, and the first plate 26 of the storage capacitor may be provided in the first conductive layer, the first initial signal line 31, the second initial signal line 32, the shielding electrode 33, and the second plate 34 may be provided in the second conductive layer, the first auxiliary connection line 38, the second auxiliary connection line 39, the second initial signal connection line 40, the first connection electrode 41, the second connection electrode 42, the third connection electrode 43, the fourth connection electrode 44, the fifth connection electrode 45, the sixth connection electrode 46, the first power supply line 47, the data line 48, the first initial signal connection line 49 and the second data transfer line 50 may be provided in the third conductive layer, the first connection ring 51, the first anode connection electrode 52, the second anode connection electrode 53, the third anode connection electrode 54, the first anode pad 55, the second anode pad 56, the third anode pad 57, and the first transmission ring 58 may be provided in the fourth conductive layer, and the first anode 71, the second anode 72, the third anode 73, the second transmission ring 74 may be provided in the anode layer.

In an exemplary implementation, the base substrate may be a flexible substrate, or a rigid substrate. The rigid base substrate may be made of, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation, the flexible substrate may include a first flexible material layer, a first inorganic material layer, a semiconductor layer, a second flexible material layer, and a second inorganic material layer which are stacked, wherein materials of the first flexible material layer and the second flexible material layer may be Polyimide (PI), Polyethylene Terephthalate (PET), or a surface-treated polymer soft film, or the like, materials of the first inorganic material layer and the second inorganic material layer may be Silicon Nitride (SiNx) or Silicon Oxide (SiOx), or the like, for improving a water and oxygen resistance capability of the substrate, and a material of the semiconductor layer may be amorphous silicon (a-si).

In an exemplary implementation, the first conductive layer, the second conductive layer, the third conductive layer, the fourth conductive layer and the anode layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, and the fourth insulation layer may be made of any one or more of Silicon Oxide (SiOx), Silicon Nitride (SiNx), and Silicon Oxynitride (SiON), and may be a single layer, a multi-layer, or a composite layer. The first insulation layer and the second insulation layer may be referred to as Gate Insulation (GI) layers, the third insulation layer is referred to as Interlayer Dielectric (ILD) layers, and the fourth insulation layer is referred to as a Passivation (PVX) layer. The fifth insulating layer and the sixth insulating layer may be referred to as planarization (PLN) layers, and the planarization layer may be made of an organic material such as a resin or the like. An active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene. That is, the present disclosure is applicable to a transistor that is manufactured based on an oxide technology, a silicon technology, or an organic matter technology. The material of the pixel definition thin film may include polyimide, acrylic, or the like.

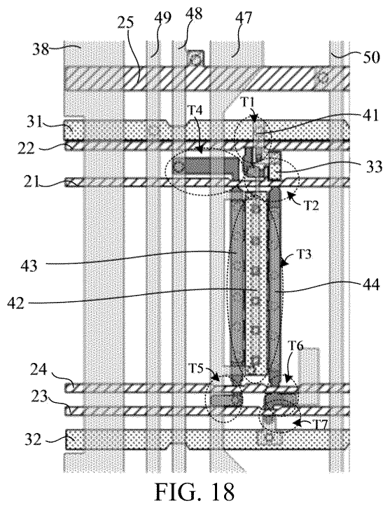

FIG. 18 is a schematic diagram of a portion of a structure of the first circuit unit in FIG. 7, illustrating the structures of the semiconductor layer to the third conductive layer.

In an exemplary implementation, the pixel drive circuit may include a plurality of (e.g., six) drive transistors arranged sequentially in one direction, first electrodes of the plurality of drive transistors are connected to each other through the third connection electrode 43, second electrodes of the plurality of drive transistors are connected to each other through the fourth connection electrode 44, and gate electrodes of the plurality of drive transistors are connected to each other through the second connection electrode 42. By providing a plurality of drive transistors in the pixel drive circuit, and connecting first electrodes, gate electrodes, and second electrodes of the plurality of drive transistors to each other, respectively, it may be advantageous to increase the drive current provided by the pixel drive circuit, thereby improving the display quality of the display substrate. For example, the second connection electrode 42 may serve as the first node N1 in the pixel circuit. The third connection electrode 43 may serve as the second node N2 in the pixel circuit. The fourth connection electrode 44 may serve as the third node N3 in the pixel circuit.

In an exemplary implementation, by providing at least one first initial signal connection line 49 extending along the second direction Y, and connecting the first initial signal connection line 49 with the first initial signal line 31 extending along the first direction X, a net-like structure for transmitting the first initial signal can be formed, and the transmission consistency of the first initial signal can be ensured.

In an exemplary implementation, by providing at least one second data transfer line 50 extending along the second direction Y, providing at least one first data transfer line 25 extending along the first direction X, and connecting the second data transfer line 50 and the first data transfer line 25, and the connection of the first data adapter line 25 to the data line 48 may be utilized, so that the data line 48 may extend from the display region to the bonding region of the lower bezel via the second data transfer line 50 and be connected to the integrated circuit to form a FIAA structure. By adopting the FIAA structure, the width of the arrangement of a plurality of fan-out traces of the lower bezel in the first direction X can be reduced, so that the size of the lower bezel can be effectively reduced, which is beneficial to realize a display substrate with a narrow bezel.

In an exemplary implementation, by providing at least one first auxiliary connection line 38 extending along the second direction Y, the connection of the first auxiliary connection line 38 and the first connection ring 51 can be used, the voltage drop of the first voltage signal can be reduced. In the exemplary embodiment, by providing an orthographic projection of the shielding electrode 33 on the base substrate to be at least partially overlapped with an orthographic projection of the second active layer between two gate electrodes of the second transistor T2 in the present circuit unit on the base substrate, and the first connection electrode 41 is used to enable the shielding electrode 33 to be connected to the first initial signal line 31, so that the shielding electrode 33 receives a constant first initial signal, thereby avoiding the influence of other signals (such as data voltage jumps) on the second transistor T2 and improving the display effect. The first connection electrode 41 may also be connected to a first electrode of the first transistor T1.

In an exemplary implementation, by providing the first notch 31-1 on the first initial signal line 31, providing the second notch 32-1 on the second initial signal line 32, and overlapping an orthographic projection of the data line 48 on the base substrate with an orthographic projection of the first notch 31-1 on the base substrate and an orthographic projection of the second notch 32-1 on the base substrate, the overlapping area of the first initial signal line 31 and the second initial signal line 32 and the data line 48 can be reduced, thereby reducing the coupling capacitance between the first initial signal line 31 and the second initial signal line 32 and the data line 48.

The aforementioned structure shown in the present disclosure and the preparation process thereof are merely exemplary description. In an exemplary implementation mode, corresponding structures may be changed and patterning processes may be added or reduced according to actual needs, which is not limited here in the present disclosure.

In an exemplary implementation, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), which is not limited here in the present disclosure.

The present disclosure also provides a method for manufacturing a display substrate, for manufacturing the display substrate according to the foregoing embodiments.

In an exemplary embodiment, the method includes forming a circuit structure layer on a base substrate; the circuit structure layer includes at least a plurality of circuit units, and at least one circuit unit includes a pixel drive circuit, and the pixel drive circuit includes a plurality of drive transistors sequentially arranged in one direction; first electrodes of the plurality of drive transistors are connected to each other, second electrodes of the plurality of drive transistors are connected to each other, and gate electrodes of the plurality of drive transistors are connected to each other.

The present disclosure also provides a display substrate, including a base substrate and a circuit structure layer disposed on the base substrate, wherein the circuit structure layer includes at least a plurality of circuit units, each circuit unit includes a pixel drive circuit, and the pixel drive circuit includes a storage capacitor and a plurality of drive transistors. The storage capacitor includes a first plate and a second plate, the first plate serves as gate electrodes of the plurality of drive transistors; the second plate is located at a side of the first plate away from the base substrate; the second plate has a plurality of first openings, and an orthographic projection of the first plate on the base substrate covers an orthographic projection of the plurality of first openings of the second plate on the base substrate. A second connection electrode located at a side of the second plate away from the base substrate is connected to the first plate through vias provided in the plurality of first openings.

In some exemplary implementations, within a single circuit unit, the first plate includes a plurality of first sub-plates, and a single first sub-plate serves as a gate electrode of at least one drive transistor. The plurality of circuit units includes at least a first circuit unit, a second circuit unit, and a third circuit unit. An area of an orthographic projection of the first sub-plate within the third circuit unit on the base substrate is smaller than an area of an orthographic projection of the first sub-plate within the second circuit unit on the base substrate. The area of the orthographic projection of the first sub-plate within the third circuit unit on the base substrate is smaller than an area of an orthographic projection of the first sub-plate within the first circuit unit on the base substrate.

In some exemplary implementations, within a single circuit unit, the second plate has a plurality of first openings. The plurality of circuit units includes at least a first circuit unit, a second circuit unit, and a third circuit unit. An area of an orthographic projection of the first opening of the second plate within the third circuit unit of the base substrate is greater than an area of an orthographic projection of the first opening of the second plate within the first circuit unit of the base substrate. The area of the orthographic projection of the first opening of the second plate within the third circuit unit of the base substrate is greater than an area of an orthographic projection of the first opening of the second plate within the second circuit unit of the base substrate. For example, an area of an orthographic projection of a single first opening within the third circuit unit on the base substrate may be greater than an area of an orthographic projection of a single first opening within the first circuit unit on the base substrate. In some examples, a total area of orthographic projections of the plurality of first openings within the third circuit unit on the base substrate may be greater than a total area of orthographic projections of the plurality of first openings within the first circuit unit of the base substrate.

In some exemplary implementations, the plurality of circuit units includes at least a first circuit unit, a second circuit unit, and a third circuit unit. A quantity of first openings of the second plate within the third circuit unit is different from a quantity of first openings of the second plate within the first circuit unit. The quantity of first openings of the second plate within the first circuit unit is the same as a quantity of first openings of the second plate within the second circuit unit.

In some exemplary implementations, the pixel drive circuit in the first circuit unit is connected to a light emitting device emitting red light, the pixel drive circuit in the second circuit unit is connected to a light emitting device emitting green light, and the pixel drive circuit in the third circuit unit is connected to a light emitting device emitting blue light.

The structure of the display substrate of the present embodiment can be referred to the foregoing embodiments and is therefore not described here.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present invention.

Although implementations disclosed in the present disclosure are described as above, the described contents are only implementations which are used for facilitating understanding of the present disclosure, but are not intended to limit the present invention. Any skilled person in the art to which the present disclosure pertains may make any modification and variation in a form and details of implementation without departing from the spirit and scope of the present disclosure. However, the patent protection scope of the present invention should be subject to the scope defined in the appended claims.

1. A display substrate comprising: a base substrate and a circuit structure layer disposed on the base substrate, wherein the circuit structure layer comprises at least a plurality of circuit units, at least one of the circuit units comprises a pixel drive circuit, the pixel drive circuit comprises a plurality of drive transistors; first electrodes of the plurality of drive transistors are connected to each other, second electrodes of the plurality of drive transistors are connected to each other, and gate electrodes of the plurality of drive transistors are connected to each other.

2. The display substrate according to claim 1, wherein the pixel drive circuit further comprises a storage capacitor, the storage capacitor comprises a first plate and a second plate, the second plate is located on a side of the first plate away from the base substrate, an orthographic projection of the first plate on the base substrate is at least partially overlapped with an orthographic projection of the second plate on the base substrate;
the first plate comprises a plurality of first sub-plates, and a single first sub-plate serves as the gate electrode of at least one of the drive transistors.

3. The display substrate according to claim 2, wherein the plurality of first sub-plates of the first plate are independently disposed and electrically connected by a second connection electrode; the second connection electrode is located on a side of the second plate away from the base substrate.

4. The display substrate according to claim 3, wherein the pixel drive circuit further comprises a first initialization transistor and a threshold compensation transistor;
a first electrode of the first initialization transistor is connected to a first initial signal line, and a second electrode of the first initialization transistor is connected to the gate electrodes of the plurality of drive transistors; a second electrode of the threshold compensation transistor is connected to the gate electrodes of the plurality of drive transistors, and a first electrode of the threshold compensation transistor is connected to the second electrodes of the plurality of drive transistors;
the first initial transistor and the threshold compensation transistor are connected to the gate electrodes of the plurality of drive transistors through the second connection electrode.

5. The display substrate according to claim 4, wherein in a direction perpendicular to the display substrate, the circuit structure layer comprises at least a semiconductor layer, a first conductive layer, a second conductive layer, and a third conductive layer disposed sequentially on the base substrate;
the first plate of the storage capacitor is located on the first conductive layer, the second plate is located on the second conductive layer, and the second connection electrode is located on the third conductive layer.

6. (canceled)

7. The display substrate according to claim 1, wherein the circuit structure layer further comprises a data line connected to the pixel drive circuit and extending along a second direction, a first data transfer line extending along a first direction, and a second data transfer line extending along the second direction; the first direction intersects the second direction;
the data line is connected to the second data transfer line through the first data transfer line; the first data transfer line is located at a side of the data line close to the base substrate, and the second data transfer line and the data line are disposed in a same layer.

8. The display substrate according to claim 7, wherein the circuit structure layer further comprises a first power supply line connected to the pixel drive circuit; the data line and the first power supply line are disposed in a same layer and arranged at intervals in the first direction.

9. The display substrate according to claim 1, wherein the pixel drive circuit further comprises a first initialization transistor, a first electrode of the first initialization transistor is connected to a first initial signal line and a second electrode of the first initialization transistor is connected to the gate electrodes of the plurality of drive transistors;
the first initial signal line extends along a first direction, the first initial signal line is connected to a first initial signal connection line extending along a second direction, and the first direction intersects the second direction;
the first initial signal connection line is located at a side of the first initial signal line away from the base substrate.

10. The display substrate according to claim 9, wherein the pixel drive circuit further comprises a second initialization transistor, a first electrode of the second initialization transistor is connected to a second initial signal line and a second electrode of the second initialization transistor is connected to a first electrode of a light emitting device to which the pixel drive circuit is connected;
the second initial signal line extends along the first direction, and the second initial signal line is connected to a second initial signal connection line extending along the second direction;
the second initial signal line and the first initial signal line are disposed in a same layer, and the second initial signal connection line and the first initial signal connection line are disposed in a same layer.

11. The display substrate according to claim 1, wherein the pixel drive circuit further comprises a first initialization transistor and a threshold compensation transistor; a first electrode of the first initialization transistor is connected to a first initial signal line, and a second electrode of the first initialization transistor is connected to the gate electrodes of the plurality of drive transistors; a second electrode of the threshold compensation transistor is connected to the gate electrodes of the plurality of drive transistors, and a first electrode of the threshold compensation transistor is connected to the second electrodes of the plurality of drive transistors;
the first initial signal line is connected to a shielding electrode, an orthographic projection of the shielding electrode on the base substrate is at least partially overlapped with an orthographic projection of a conductivized region between channel regions of an active layer of the threshold compensation transistor on the base substrate; the shielding electrode and the first initial signal line are disposed in a same layer, and are located at a side of a gate electrode of the threshold compensation transistor away from the base substrate.

12. The display substrate according to claim 11, wherein the first initial signal line is connected to the shielding electrode and the first initialization transistor through a first connection electrode; the first connection electrode is located at a side of the first initial signal line away from the base substrate.

13. The display substrate according to claim 1, wherein the plurality of circuit units are divided into a plurality of circuit unit groups, each circuit unit group comprises three pixel drive circuits arranged sequentially along a first direction, each pixel drive circuit in the circuit unit group is electrically connected to a first power supply line extending along a second direction;
the circuit structure layer further comprises at least one first connection ring, the first connection ring is electrically connected to three first power supply lines connected to the three pixel drive circuits in the circuit unit group, and an orthographic projection of the first connection ring on the base substrate surrounds a periphery of the three pixel drive circuits;
the first connection ring is located at a side of the first power supply line away from the base substrate.

14. The display substrate according to claim 13, wherein the circuit structure layer further comprises at least one first transmission ring, the first transmission ring and the first connection ring are disposed in a same layer, and located at a periphery of the first connection ring; the first transmission ring and the first connection ring are configured to transmit different voltage signals.

15. The display substrate according to claim 14, further comprising a light emitting structure layer located at a side of the circuit structure layer away from the base substrate, the light emitting structure layer comprises a plurality of light emitting devices;
three first pixel drive circuits in one circuit unit group are electrically connected to three light emitting devices in one-to-one correspondence;
the light emitting structure layer comprises an anode layer, the anode layer comprises anodes of the plurality of light emitting devices and at least one second transmission ring; the second transmission ring is electrically connected to the first transmission ring, an orthographic projection of the second transmission ring on the base substrate is at least partially overlapped with an orthographic projection of the first transmission ring on the base substrate; the second transmission ring is located at a periphery of anodes of the three light emitting devices to which the three first pixel drive circuits of the circuit unit group are connected.

16. The display substrate according to claim 13, further comprising a light emitting structure layer located at a side of the circuit structure layer away from the base substrate, the light emitting structure layer comprises a plurality of light emitting devices;
wherein the circuit structure layer further comprises a plurality of anode pads electrically connected to the first power supply line; the anode pad is located at a side of an anode of the light emitting device close to the base substrate, an orthographic projection of the anode pad on the base substrate comprises an orthographic projection of the anode of at least one of the light emitting devices on the base substrate;
a plurality of anode pads located on an inside of the first connection ring and the first connection ring are of an interconnected integral structure.

17-18. (canceled)

19. A preparation method of a display substrate, comprising:
forming a circuit structure layer on a base substrate; wherein the circuit structure layer comprises at least a plurality of circuit units, at least one circuit unit comprises a pixel drive circuit, and the pixel drive circuit comprises a plurality of drive transistors; first electrodes of the plurality of drive transistors are connected to each other, second electrodes of the plurality of drive transistors are connected to each other, and gate electrodes of the plurality of drive transistors are connected to each other.

20. A display substrate, comprising:
a base substrate and a circuit structure layer disposed on the base substrate, wherein the circuit structure layer comprises at least a plurality of circuit units, each circuit unit comprises a pixel drive circuit, the pixel drive circuit comprises a storage capacitor and a plurality of drive transistors;
the storage capacitor comprises a first plate and a second plate, the first plate serves as gate electrodes of the plurality of drive transistors; the second plate is located at a side of the first plate away from the base substrate; the second plate has a plurality of first openings, an orthographic projection of the first plate on the base substrate covers an orthographic projection of the plurality of first openings of the second plate on the base substrate;
a second connection electrode located at a side of the second plate away from the base substrate is connected to the first plate through vias provided in the plurality of first openings.

21. The display substrate according to claim 20, wherein within a single circuit unit, the first plate comprises a plurality of first sub-plates, a single first sub-plate serves as a gate electrode of at least one drive transistor; the plurality of circuit units comprises at least a first circuit unit, a second circuit unit, and a third circuit unit;
an area of an orthographic projection of the first sub-plate in the third circuit unit on the base substrate is less than an area of an orthographic projection of the first sub-plate in the second circuit unit on the base substrate;
the area of the orthographic projection of the first sub-plate in the third circuit unit on the base substrate is less than an area of an orthographic projection of the first sub-plate in the first circuit unit on the base substrate.

22. The display substrate according to claim 20, wherein within a single circuit unit, the second plate has a plurality of first openings; the plurality of circuit units comprises at least a first circuit unit, a second circuit unit, and a third circuit unit;
an area of an orthographic projection of the first opening of the second plate within the third circuit unit on the base substrate is greater than an area of an orthographic projection of the first opening of the second plate within the first circuit unit on the base substrate;
the area of the orthographic projection of the first opening of the second plate within the third circuit unit on the base substrate is greater than an area of an orthographic projection of the first opening of the second plate within the second circuit unit on the base substrate.

23. The display substrate according to claim 20, wherein the plurality of circuit units comprises at least a first circuit unit, a second circuit unit, and a third circuit unit;
a quantity of the first openings of the second plate within the third circuit unit that is different from a quantity of the first openings of the second plate within the first circuit unit;
the quantity of the first openings of the second plate within the first circuit unit is same as a quantity of the first openings of the second plate within the second circuit unit.

24. (canceled)
